(19) United States
(12) Patent Application Publication
(10) Pub. No.: US 2026/0314415 A1
(43) Pub. Date: Oct. 8, 2026

(54) SEMICONDUCTOR PACKAGE WITH STACKED MEMBERS

(71) Applicant: Samsung Electronics Co., Ltd., Suwon-si (KR)

(72) Inventors: Minyoung Lee, Suwon-si (KR); Jongyoun Kim, Suwon-si (KR); Myeonghan Bae, Suwon-si (KR)

(73) Assignee: Samsung Electronics Co., Ltd., Suwon-si (KR)

(21) Appl. No.: 19/438,244

(22) Filed: Dec. 31, 2025

(30) Foreign Application Priority Data
Apr. 7, 2025 (KR) 10-2025-0044925

(51) Int. Cl. H10W 40/80; H10W 42/00; H10W 46/00; H10W 72/00; H10W 74/10; H10W 90/24

(52) U.S. Cl. CPC H10W 40/80; H10W 42/121; H10W 46/201; H10W 46/401; H10W 72/823; H10W 74/121; H10W 90/24

(57) ABSTRACT

A semiconductor package includes a lower redistribution wiring layer having redistribution wirings, a molding member stacked on the lower redistribution wiring layer and having a first surface facing the lower redistribution wiring layer and a second surface opposite to the first surface, a plurality of semiconductor chips sequentially stacked within the molding member and arranged such that front surfaces on which chip pads are formed face the lower redistribution wiring layer, conductive pillars extending substantially vertically from the chip pads within the molding member and electrically connected to the redistribution wirings, respectively, an upper redistribution wiring layer provided on the second surface of the molding member, and a silicon layer provided on the upper redistribution wiring layer and having a marking pattern formed in an outer surface of the silicon layer.

### CROSS-REFERENCE TO RELATED APPLICATIONS

This present application claims priority to and the benefit under 35 U.S.C. § 119(a)-(d) of Korean Patent Application No. 10-2025-0044925, filed on Apr. 7, 2025 in the Korean Intellectual Property Office, the entire disclosure of which is incorporated herein by reference.

### FIELD

Example embodiments relate to a semiconductor package and a method of manufacturing the semiconductor package. More particularly, example embodiments relate to a multi-chip package including a plurality of stacked chips and a method of manufacturing the same.

### BACKGROUND

In manufacturing a fan out package using vertical wires, the vertical wires may be formed on chip pads of sequentially stacked semiconductor chips by a bonding wire process, and a molding member may be formed to cover the semiconductor chips and the vertical wires by a molding process. However, there are problems in that the cost of forming the vertical wires is high and the process time increases. In addition, since a separate marking layer must be formed in order to form a marking pattern, there is a problem in that the number of processes increases.

### SUMMARY

Example embodiments provide a semiconductor package having improved heat dissipation performance and capable of reducing package manufacturing cost and process time.

Example embodiments provide a method of manufacturing the semiconductor package.

According to example embodiments, a semiconductor package includes a lower redistribution wiring layer having redistribution wirings, a molding member stacked on the lower redistribution wiring layer and having a first surface facing the lower redistribution wiring layer and a second surface opposite to the first surface, a plurality of semiconductor chips sequentially stacked within the molding member and arranged such that front surfaces on which chip pads are formed face the lower redistribution wiring layer, conductive pillars extending substantially vertically from the chip pads within the molding member and electrically connected to the redistribution wirings, respectively, an upper redistribution wiring layer provided on the second surface of the molding member, and a silicon layer provided on the upper redistribution wiring layer and having a marking pattern formed in an outer surface of the silicon layer.

According to example embodiments, a semiconductor package includes a lower redistribution wiring layer having redistribution wirings, a first encapsulation structure stacked on the lower redistribution wiring layer, a second encapsulation structure stacked on the first encapsulation structure, and a silicon layer provided on the second encapsulation structure and having a marking pattern formed in an outer surface of the silicon layer. The first encapsulation structure includes a lower molding member having a first surface in contact with the lower redistribution wiring layer and a second surface opposite to the first surface, a plurality of lower semiconductor chips sequentially arranged within the lower molding member such that front surfaces on which chip pads are formed face the lower redistribution wiring layer, lower conductive pillars extending substantially vertically from the chip pads within the lower molding member and electrically connected to the redistribution wirings, respectively, and an intermediate redistribution wiring layer provided on the second surface of the lower molding member. The second encapsulation structure includes an upper molding member having a third surface in contact with the intermediate redistribution wiring layer and a fourth surface opposite to the third surface, a plurality of upper semiconductor chips sequentially arranged within the upper molding member such that front surfaces on which chip pads are formed face the lower redistribution wiring layer, upper conductive pillars extending substantially vertically from the chip pads within the upper molding member, and an upper redistribution wiring layer provided on the fourth surface of the upper molding member.

According to example embodiments, a semiconductor package includes a lower redistribution wiring layer having redistribution wirings, a lower molding member stacked on the lower redistribution wiring layer and having a first surface facing the lower redistribution wiring layer and a second surface opposite to the first surface, a plurality of lower semiconductor chips sequentially arranged within the lower molding member such that front surfaces on which chip pads are formed face the lower redistribution wiring layer, lower conductive pillars extending substantially vertically from the chip pads within the lower molding member and electrically connected to the redistribution wirings, respectively, an intermediate redistribution wiring layer provided on the second surface of the lower molding member, an upper molding member having a third surface contacting the intermediate redistribution wiring layer and a fourth surface opposite to the third surface, a plurality of upper semiconductor chips sequentially arranged within the upper molding member such that front surfaces on which chip pads are formed faces the intermediate redistribution wiring layer, upper conductive pillars extending substantially vertically from the chip pads within the upper molding member, an upper redistribution wiring layer provided on the fourth surface of the upper molding member, and a silicon layer provided on the upper redistribution wiring layer and having a marking pattern formed in an outer surface of the silicon layer.

According to example embodiments, a semiconductor package may include a lower redistribution wiring layer, first and second encapsulation structures stacked on the lower redistribution layer, and a marking layer provided on the second encapsulation structure.

After the second encapsulation structure, the first encapsulation structure, and the lower redistribution wiring layer are formed on a carrier substrate including silicon, a backside surface of the carrier substrate may be partially removed to form the marking layer having a desired thickness, and a laser may be irradiated on a surface of the marking layer to form a marking pattern. Accordingly, the backside surface of the carrier substrate may be ground and utilized as the marking layer without forming a separate marking layer. Thus, the package manufacturing process may be simplified and the cost may be reduced.

In addition, since the marking layer including silicon has high thermal conductivity and strength, the heat dissipation performance of the semiconductor package may be improved and warpage of the semiconductor package may be prevented or reduced.

### BRIEF DESCRIPTION OF THE DRAWINGS

Example embodiments will be more clearly understood from the following detailed description taken in conjunction with the accompanying drawings. FIGS. 1 to 42 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is an enlarged cross-sectional view illustrating portion ‘B’ in FIG. 1.

FIG. 4 is a bottom view illustrating a first encapsulation structure of the semiconductor package of FIG. 1.

FIG. 5 is a bottom view illustrating a second encapsulation structure of the semiconductor package of FIG. 1.

FIGS. 6 to 34 are views illustrating a method of manufacturing a semiconductor package in accordance with example embodiments.

FIG. 35 is a cross-sectional view illustrating a semiconductor package in accordance with example embodiments.

FIGS. 36 to 42 are cross-sectional views illustrating a method of manufacturing a semiconductor package in accordance with example embodiments.

### DETAILED DESCRIPTION

Hereinafter, example embodiments will be explained in detail with reference to the accompanying drawings.

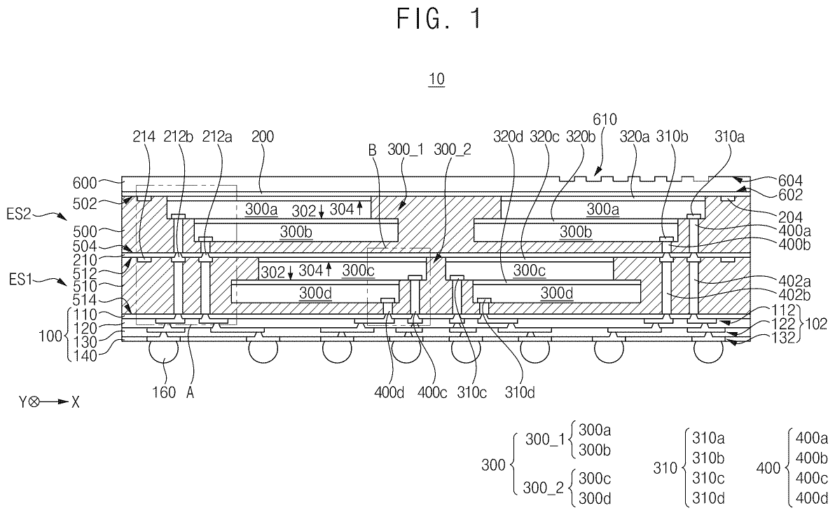

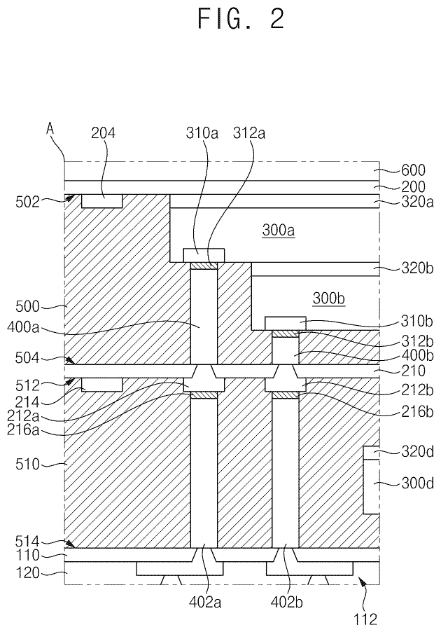

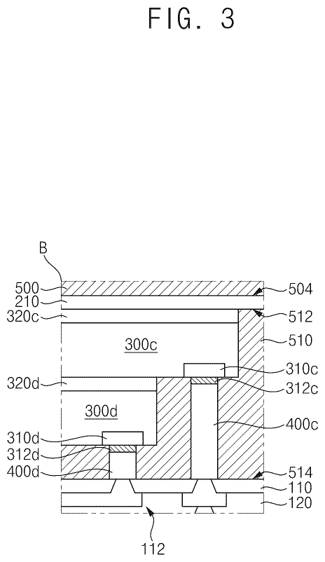

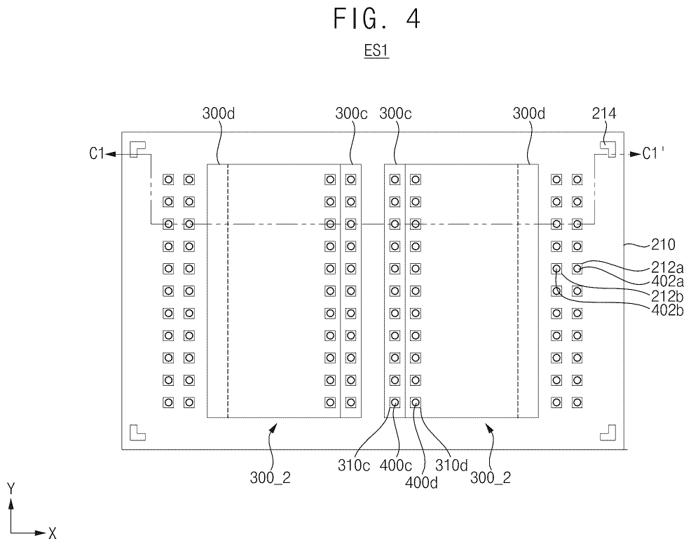

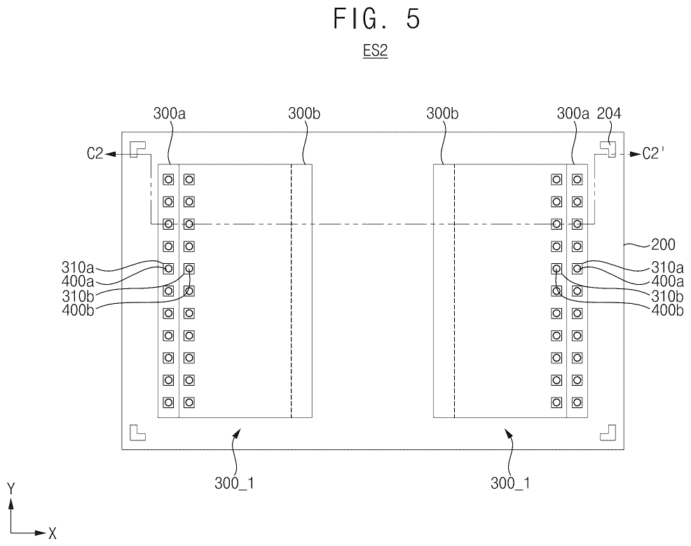

FIG. 1 is a cross-sectional view illustrating a semiconductor package in accordance with example embodiments. FIG. 2 is an enlarged cross-sectional view illustrating portion ‘A’ in FIG. 1. FIG. 3 is an enlarged cross-sectional view illustrating portion ‘B’ in FIG. 1. FIG. 4 is a bottom view illustrating a first encapsulation structure of the semiconductor package of FIG. 1. FIG. 5 is a bottom view illustrating a second encapsulation structure of the semiconductor package of FIG. 1. FIG. 1 includes a cross-section cut along the line C1-C1′ in FIG. 4 and a cross-section cut along the line C2-C2′ in FIG. 5. The cutting lines C1-C1′ and C2-C2′ overlap each other when viewed in plan view. FIG. 4 represents a state where a lower molding member is omitted, and FIG. 5 represents a state where an upper molding member is omitted.

Referring to FIGS. 1 to 5, a semiconductor package 10 may include a lower redistribution wiring layer 100, a first encapsulation structure ES1 disposed on the lower redistribution wiring layer 100, a second encapsulation structure ES2 stacked on the first encapsulation structure ES1, and a marking layer 600 provided on the second encapsulation structure ES2. In addition, the semiconductor package 10 may further include external connection members 160 disposed on an outer surface of the lower redistribution wiring layer 100.

In example embodiments, the semiconductor package 10 may be a fan-out package in which the lower redistribution wiring layer 100 is formed to extend beyond a region where the semiconductor chips 300_1, 300_2 are arranged. The lower redistribution wiring layer 100 may be formed by a wafer-level redistribution wiring process. In addition, the semiconductor package 10 may be provided as an upper package that is stacked on a lower package.

Additionally, the semiconductor package 10 may be provided as System In Package (SIP). For example, one or more semiconductor chips may be disposed on the lower redistribution wiring layer 100. The semiconductor chips may include a logic chip including a logic circuit and/or a memory chip. The logic chip may be a controller that controls memory chips. The memory chip includes various types of memory circuits, such as DRAM, SRAM, flash, PRAM, ReRAM, FeRAM, or MRAM.

In example embodiments, the lower redistribution wiring layer 100 may have redistribution wirings 102. The first encapsulation structure ES1 including a plurality of lower semiconductor chips 300_2 electrically connected to the redistribution wirings 102 and the second encapsulation structure ES2 including a plurality of upper semiconductor chips 300_1 electrically connected to the redistribution wirings 102 may be stacked on the lower redistribution wiring layer 100. The lower redistribution wiring layer 100 may be a front redistribution layer (FRDL) of the fan-out package.

In particular, the lower redistribution wiring layer 100 may include a plurality of insulating layers, i.e., first, second, third and fourth lower insulating layers 110, 120, 130 and 140 and the redistribution wirings 102 provided in the first, second, third and fourth lower insulating layers. The redistribution wirings 102 may include first, second and third lower redistribution wirings 112, 122 and 132.

The first, second, third and fourth lower insulating layers may include a polymer, a dielectric layer, etc. For example, the first, second, third and fourth lower insulating layers may include a photosensitive insulating layer such as PID (Photo Imageable Dielectric). The first, second, third and fourth lower insulating layers may be formed by a vapor deposition process, a spin coating process, etc. The redistribution wirings may include aluminum (Al), copper (Cu), tin (Sn), nickel (Ni), gold (Au), platinum (Pt), or an alloy thereof. The redistribution wirings may be formed by a plating process, an electroless plating process, a vapor deposition process, etc.

In particular, the first lower insulating layer 110 may be formed on a first surface 514 of a lower molding member 510, and the first lower redistribution wirings 112 may be formed on the first lower insulating layer 110. As described below, the first lower redistribution wirings 112 may be electrically connected to second conductive pillars 400c, 400d and conductive connection pillars 402a, 402b that are exposed from a first surface 312 of the lower molding member 510 through first openings formed in the first lower insulating layer 120.

The second lower insulating layer 120 may be formed on the first lower insulating layer 110, and the second lower redistribution wirings 122 may be formed on the second lower insulating layer 120. The second lower redistribution wirings 122 may be electrically connected to the first lower redistribution wirings 112 through second openings formed in the second lower insulating layer 120.

The third lower insulating layer 130 may be formed on the second lower insulating layer 120, and the third lower redistribution wirings 132 may be formed on the third lower insulating layer 130. The third lower redistribution wirings 132 may be electrically connected to the second lower redistribution wirings 122 through third openings formed in the third lower insulating layer 130.

The fourth lower insulating layer 140 may be formed on the third lower insulating layer 130 to expose at least portions of the third lower redistribution wirings 132. The fourth lower insulating layer 140 may serve as a passivation layer.

It will be understood that the number, size, arrangement, etc. of the lower insulating layers and the redistribution wirings of the lower redistribution wiring layer are provided as an example, and the present inventive concept is not limited thereto.

In example embodiments, when viewed in plan view, the lower redistribution wiring layer 100 may include a first region overlapping the semiconductor chips 300 of the firsts and second encapsulation structures ES1, ES2 disposed on an upper surface of the lower redistribution wiring layer 100 and a second region surrounding the first region. The second region may be a fan-out region outside the region where the semiconductor chips are disposed.

In example embodiments, the first encapsulation structure ES1 may include a lower molding member 510, a plurality of lower semiconductor chips 300_2 arranged within the lower molding member 510, a plurality of first conductive pillars 400 as vertical conductive structures extending vertically from chip pads 310 of the lower semiconductor chips 300_2 within the lower molding member 510, and an intermediate redistribution wiring layer 210 provided on the lower molding member 510.

The lower molding member 510 may have a first surface 514 that contacts the lower redistribution wiring layer 100 and a second surface 512 that is opposite to the first surface 514. For example, the lower molding member 510 may include a thermosetting resin, for example, epoxy mold compound EMC. The lower molding member 510 may include fillers and epoxy resin that acts as a binder for the fillers.

The plurality of lower semiconductor chips 300_2 may include third and fourth semiconductor chips 300c, 300d sequentially stacked within the lower molding member 510. The plurality of lower semiconductor chips 300_2 may be arranged such that a front surface 302 on which chip pads 310c, 310d are formed faces the lower redistribution wiring layer 100. Each of the lower semiconductor chips 300_2 may have a rectangular shape having four sides when viewed in plan view. A first side and a third side of each of the lower semiconductor chips 300_2 may be arranged to be parallel to a first direction (X direction), and a second side and a fourth side of each of the lower semiconductor chips may be arranged to be parallel to a second direction (Y direction) perpendicular to the first direction. The chip pads 310c, 310d may be arranged in an edge region along one side (the second side) of each of the lower semiconductor chips 300. The chip pads 310c, 310d may be arranged to be spaced apart from each other in the second direction (Y direction) on the front surface 302 of each of the third and fourth semiconductor chips 300c, 300d. It will be understood that the number, arrangement, etc. of the lower semiconductor chips are provided as an example, and the present inventive concept is not limited thereto. For example, the chip pads 310c, 310d may be arranged in an edge region along the first side or the third side of each of the third and fourth semiconductor chips 300c, 300d.

In particular, the plurality of semiconductor chips 300 may include the third and fourth semiconductor chips 300c, 300d that are stacked in a cascade manner on the intermediate redistribution wiring layer 210. The third and fourth semiconductor chips 300c, 300d may be sequentially attached to a surface of the intermediate redistribution wiring layer 210 using adhesive members 320c, 320d. The adhesive members may include an adhesive film such as a die attach film (DAF). For example, a thickness of the semiconductor chip may be within a range of 35 μm to 50 μm. A thickness of the adhesive member may be within a range of 5 μm to 15 μm.

The fourth semiconductor chip 300d may be offset aligned in a first horizontal direction (X direction) with respect to the third semiconductor chip 300c. The fourth semiconductor chip 300d may be offset aligned in a first horizontal direction (X direction) such that the chip pads 310c of the third semiconductor chip 300c are exposed from the fourth semiconductor chip 300d.

The third semiconductor chip 300c may have an overhang portion protruding from one side of the fourth semiconductor chip 300d. When viewed from the bottom view of FIG. 4, the chip pads 310c of the third semiconductor chip 300c may be arranged on a lower surface, i.e., the front surface 302 of the overhang portion protruding from one side (second side) of the fourth semiconductor chips 400d to be spaced apart from each other along a second horizontal direction (Y direction) perpendicular to the first horizontal direction. It will be understood that the arrangement of the fourth semiconductor chip is provided as an example, and the present inventive concept is not limited thereto. For example, the fourth semiconductor chip 300d may be aligned with an offset in the second horizontal direction (Y direction) on the third semiconductor chip 300c. At this time, the chip pads 310c of the third semiconductor chip 300c may be placed in an edge region along the first side or the third side of the third semiconductor chip 300c.

The plurality of lower semiconductor chips 300_2 may include a memory chip including memory circuits. For example, the semiconductor chip may include volatile memory devices such as SRAM devices or DRAM devices, and the like, and nonvolatile memory devices such as flash memory devices, PRAM devices, MRAM devices or RRAM devices.

For example, two third semiconductor chips 300c may be arranged to be spaced apart from each other in the first direction (X direction), and two fourth semiconductor chips 300d may be arranged on the two third semiconductor chips 300c, respectively. Accordingly, two first chip stack structures 300_2 each including the third and fourth semiconductor chips 300c, 300d sequentially stacked on each other may be arranged to be spaced apart from each other in the first direction (X direction).

It will be understood that the number, size, arrangement, etc. of the lower semiconductor chips are provided as an example, and the present inventive concept is not limited thereto. For example, each of the first chip stack structures 300_2 may include three or more stacked semiconductor chips. In addition, although only a few chip pads are illustrated in the figures, it will be understood that the structure, shape, and arrangement of the chip pads are provided as an example, and that the present inventive concept is not limited thereto.

In example embodiments, the first conductive pillars 400c, 400d as lower conductive pillars may extend vertically on the chip pads 310c, 310d of the third and fourth semiconductor chips 300c, 300d within the lower molding member 510, respectively. When viewed from bottom view, the first conductive pillars 400c, 400d may be provided within the area where the third and fourth semiconductor chips 300c, 300d are placed.

The first conductive pillars 400c, 400d may be formed by a TDV (Through Dielectric Via) manufacturing method. The first conductive pillars 400c, 400d may be formed by a plating process. Seed layer patterns 312c, 312d may be provided on the chip pads 310c, 310d of the third and fourth semiconductor chips 300c, 300d, respectively, and the first conductive pillars 400c, 400d may be provided on the seed layer patterns 312c, 312d, respectively. The first conductive pillars 400c, 400d may include a metal material such as copper (Cu).

The intermediate redistribution wiring layer 210 may include at least one insulating layer. The insulating layer may include a polymer, a dielectric layer, etc. The insulating layer may be formed by a vapor deposition process, a spin coating process, etc. Second alignment key patterns 214 may be provided on a lower surface of the intermediate redistribution wiring layer 210. A process of attaching the lower semiconductor chips may be performed using the second alignment key patterns 214.

In example embodiments, the second encapsulation structure ES2 may include an upper molding member 500, a plurality of upper semiconductor chips 300_1 arranged within the upper molding member 500, a plurality of second conductive pillars 400 as vertical conductive structures extending vertically from chip pads 310 of the plurality of upper semiconductor chips 300_1 within the upper molding member 500, and an upper redistribution wiring layer 200 provided on the upper molding member 500.

The upper molding member 500 may have a third surface 504 in contact with the intermediate redistribution wiring layer 210 and a fourth surface 502 opposite to the third surface 504. For example, the second molding member 500 may include a thermosetting resin, for example, epoxy mold compound EMC.

The plurality of upper semiconductor chips 300_1 may include first and second semiconductor chips 300a, 300b sequentially stacked within the upper molding member 500. The plurality of upper semiconductor chips 300_1 may be arranged such that a front surface 302 on which chip pads 310a, 310b are formed faces the lower redistribution wiring layer 100. Each of the upper semiconductor chips 300_1 may have a rectangular shape having four sides when viewed in plan view. A first side and a third side of each of the upper semiconductor chips 300_1 may be arranged to be parallel to the first direction (X direction), and a second side and a fourth side of each of the upper semiconductor chips may be arranged to be parallel to the second direction (Y direction) perpendicular to the first direction. The chip pads 310a, 310b may be arranged in an edge region along one side (the second side) of each of the upper semiconductor chips 300. The chip pads 310a, 310b may be arranged to be spaced apart from each other in the second direction (Y direction) on the front surface 302 of each of the first and second semiconductor chips 300a, 300b. It will be understood that the number, arrangement, etc. of the upper semiconductor chips are provided as an example, and the present inventive concept is not limited thereto. For example, the chip pads 310a, 310b may be arranged in an edge region along the first side or the third side of each of the first and second semiconductor chips 300a, 300b.

In particular, the plurality of upper semiconductor chips 300 may include the first and second semiconductor chips 300a, 300b that are stacked in a cascade manner on the upper redistribution wiring layer 200. The first and second semiconductor chips 300a, 300b may be sequentially attached to a surface of the upper redistribution wiring layer 200 using adhesive members 320a, 320b. The adhesive members may include an adhesive film such as a die attach film (DAF). For example, a thickness of the semiconductor chip may be within a range of 35 μm to 50 μm. A thickness of the adhesive film may be within a range of 5 μm to 15 μm.

The second semiconductor chip 300b may be offset aligned in the first horizontal direction (X direction) with respect to the first semiconductor chip 300a. The second semiconductor chip 300b may be offset aligned in the first horizontal direction (X direction) such that the chip pads 310a of the first semiconductor chip 300a are exposed.

The first semiconductor chip 300a may include an overhang portion protruding from one side of the second semiconductor chip 300b that is disposed below the first semiconductor chip 300. When viewed from the bottom view of FIG. 5, the chip pads 310a of the first semiconductor chip 300a may be arranged on a lower surface, i.e., the front surface 302 of the overhang portion protruding from one side (second side) of the second semiconductor chip 300b to be spaced apart from each other along the second horizontal direction (Y direction). It will be understood that the arrangement of the second semiconductor chip is provided as an example, and the present inventive concept is not limited thereto. For example, the second semiconductor chip 300b may be aligned with an offset in the second horizontal direction (Y direction) on the first semiconductor chip 300a. At this time, the chip pads 310a of the first semiconductor chip 300a may be arranged in an edge region along the first side or the third side of the first semiconductor chip 300a.

The plurality of upper semiconductor chips 300_1 may include a memory chip including a memory circuit. For example, the semiconductor chip may include volatile memory devices such as SRAM devices or DRAM devices, and the like, and nonvolatile memory devices such as flash memory devices, PRAM devices, MRAM devices or RRAM devices.

For example, two first semiconductor chips 300a may be arranged to be spaced apart from each other in the first direction (X direction), and two second semiconductor chips 300b may be arranged on the two first semiconductor chips 300a, respectively. Accordingly, two second chip stack structures 300_1 each including the first and second semiconductor chips 300a, 300b sequentially stacked on each other may be arranged to be spaced apart from each other in the first direction (X direction).

It will be understood that the number, size, arrangement, etc. of the upper semiconductor chips are provided as an example, and the present inventive concept is not limited thereto. For example, each of the second chip stack structures 300_1 may include three or more stacked semiconductor chips. In addition, although only a few chip pads are illustrated in the figures, it will be understood that the structure, shape, and arrangement of the chip pads are provided as an example, and that the present inventive concept is not limited thereto.

In example embodiments, the second conductive pillars 400a, 400b as upper conductive pillars may extend vertically on the chip pads 310a, 310b of the first and second semiconductor chips 300a, 300b within the upper molding member 500, respectively. When viewed from bottom view, the second conductive pillars 400a, 400b may be provided within the area where the first and second semiconductor chips 300a, 300b are placed.

The second conductive pillars 400a, 400b may be formed by a TDV (Through Dielectric Via) manufacturing method. The second conductive pillars 400a, 400b may be formed by a plating process. Seed layer patterns 312a, 312b may be provided on the chip pads 310a, 310b of the first and second semiconductor chips 300a, 300b, respectively, and the second conductive pillars 400a, 400b may be provided on the seed layer patterns 312a, 312b, respectively. The second conductive pillars 400a, 400b may include a metal material such as copper (Cu).

The upper redistribution wiring layer 200 may include at least one insulating layer. The insulating layer may include a polymer, a dielectric layer, etc. The insulating layer may be formed by a vapor deposition process, a spin coating process, etc. First alignment key patterns 204 may be provided on a lower surface of the upper redistribution wiring layer 200. A process of attaching the upper semiconductor chips may be performed using the second alignment key patterns 214.

In example embodiments, the marking layer 600 may be provided on the upper redistribution wiring layer 200. A marking pattern 610 may be provided in an outer surface of the marking layer 600. The marking pattern 610 may include an engraved pattern defined by a plurality of openings formed by irradiating a laser on the outer surface of the marking layer 600. The opening may include a groove having a preset depth. The engraved pattern may indicate a manufacturer, a manufacturing date, a serial number, etc.

For example, a thickness of the marking layer 600 may be within a range of 20 μm to 100 μm. The marking layer 600 may be a silicon layer including silicon. The marking layer 600 including silicon may have a thermal conductivity of about 139.4 W/mK. The thermal conductivity of the upper and lower molding members 500, 510 may be within a range of 1.8 W/mK to 3 W/mK. Accordingly, the marking layer 600 having high thermal conductivity may be overlapped to cover the front surfaces of the upper and lower molding members 500, 510, thereby improving the heat dissipation performance of the semiconductor package 10. In addition, since the marking layer 600 including silicon has relatively high strength, warpage of the semiconductor package 10 may be prevented.

In example embodiments, the external connection members 160 may be disposed on the lower surface of the lower redistribution wiring layer 100. For example, each of the external connection members 160 may include a pillar bump 162 formed on the lower bonding pad on the third lower redistribution wiring 132 exposed by the fourth lower insulating layer 140 and a solder bump 164 on the pillar bump 162. For example, the pillar bump may include copper (Cu), aluminum (Al), tin (Sn), nickel (Ni), gold (Au), platinum (Pt), or an alloy thereof. The solder bump may include solder. The semiconductor package 10 may be mounted on a lower package, an interposer, a package substrate, etc. via the external connection members 160 to form a package-on-package (POP) device.

As mentioned above, the semiconductor package 10 may include the lower redistribution wiring layer 100, the first and second encapsulation structures ES1, ES2 stacked on the lower redistribution wiring layer 100, and the marking layer 600 provided on the second encapsulation structure ES2.

After forming the second and first encapsulation structures ES1, ES2 and the lower redistribution wiring layer 100 on the carrier substrate including silicon, the backside surface of the carrier substrate may be partially removed to form a silicon layer having a desired thickness, and a laser may be irradiated on a surface of the silicon layer to form the marking pattern. Accordingly, the backside surface of the carrier substrate may be ground and utilized as the marking layer without forming a separate marking layer. Thus, manufacturing process may be simplified and manufacturing costs may be reduced.

In addition, since the marking layer 600 including silicon has high thermal conductivity and strength, the heat dissipation performance of the semiconductor package 10 may be improved and warpage of the semiconductor package 10 may be prevent or reduced.

Hereinafter, a method of manufacturing the semiconductor package in FIG. 1 will be explained.

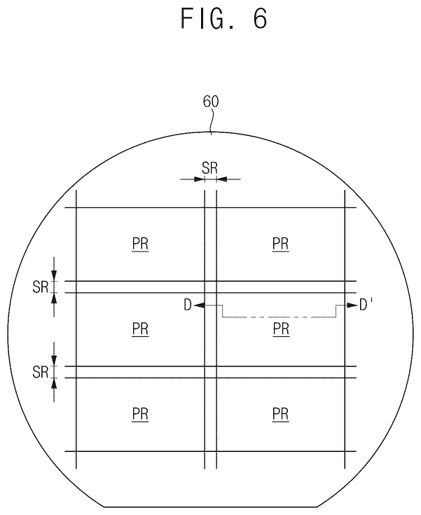

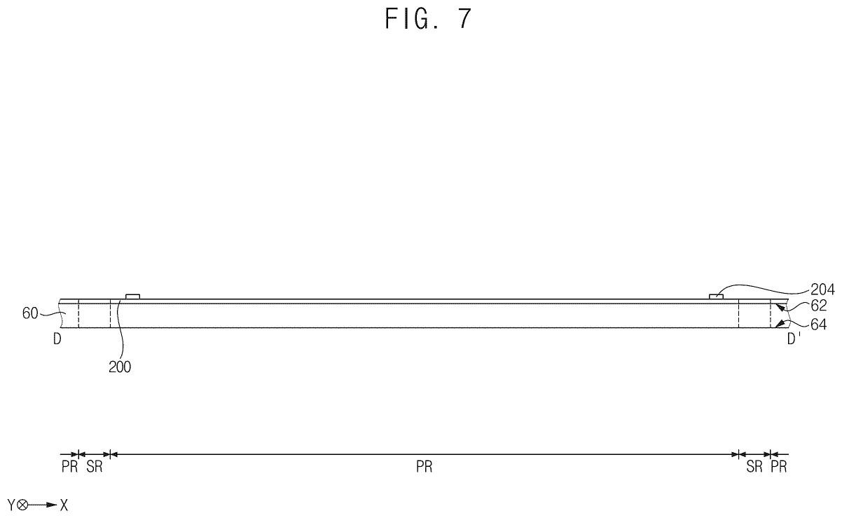

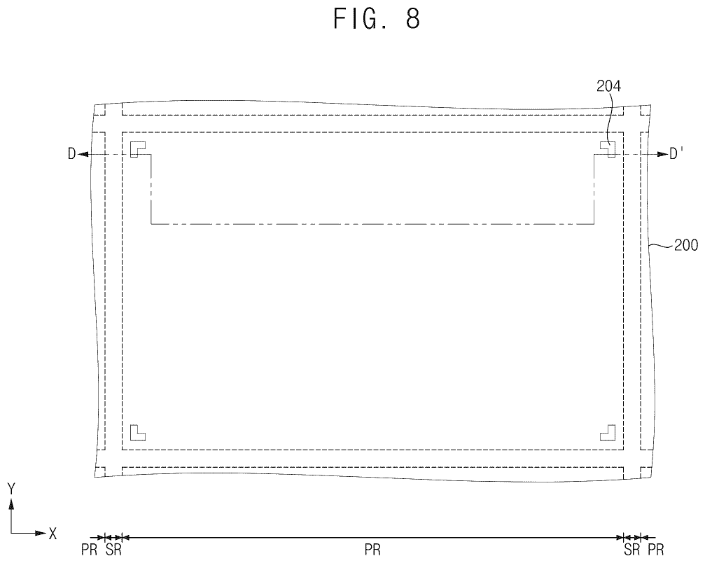

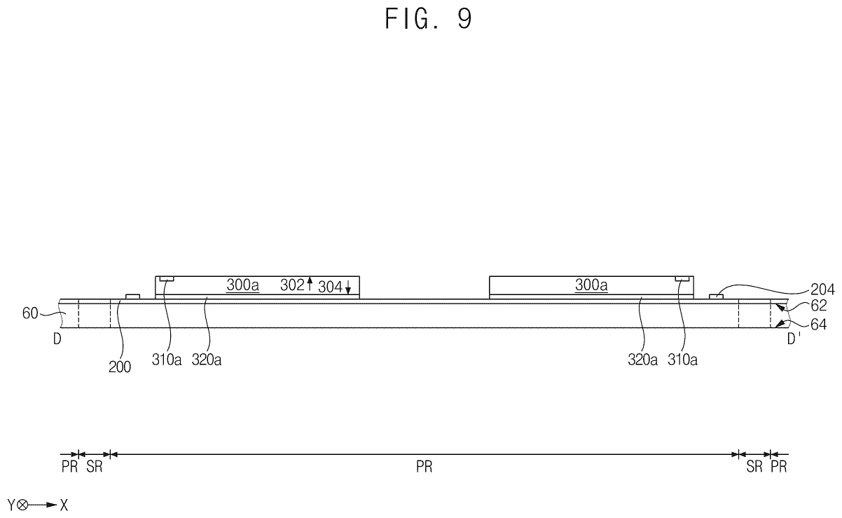

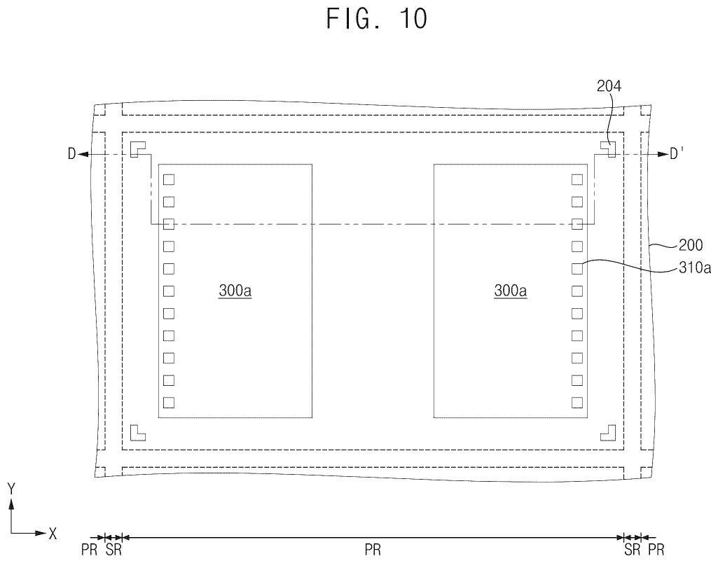

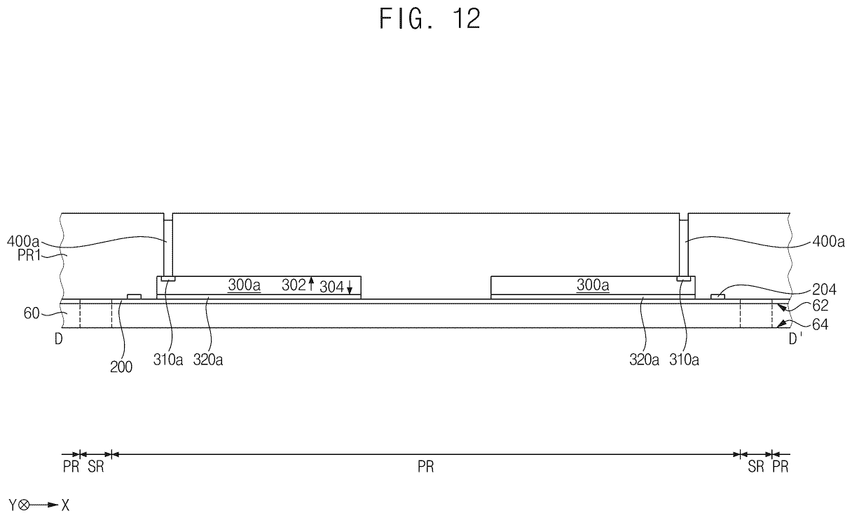

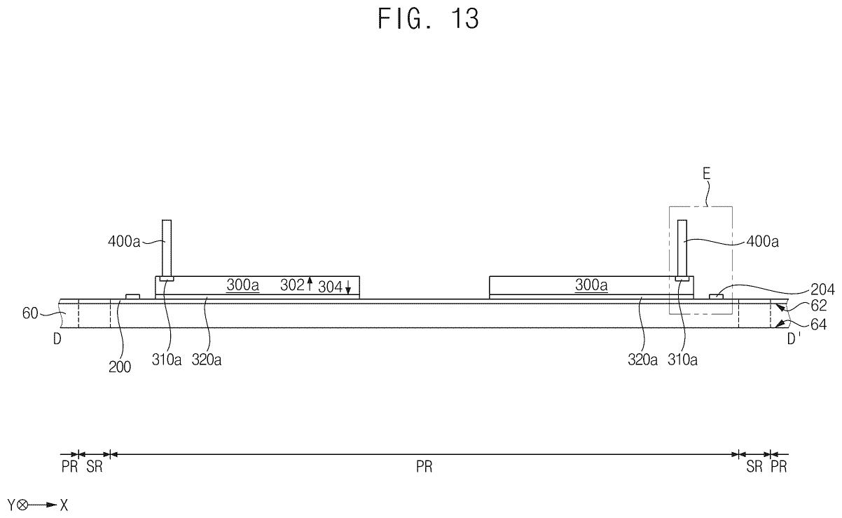

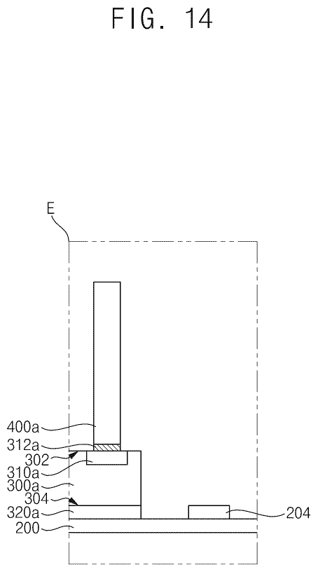

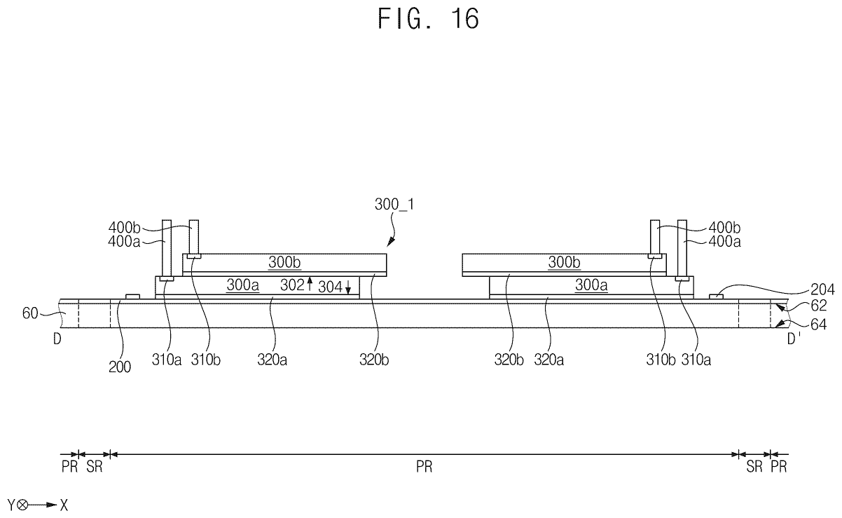

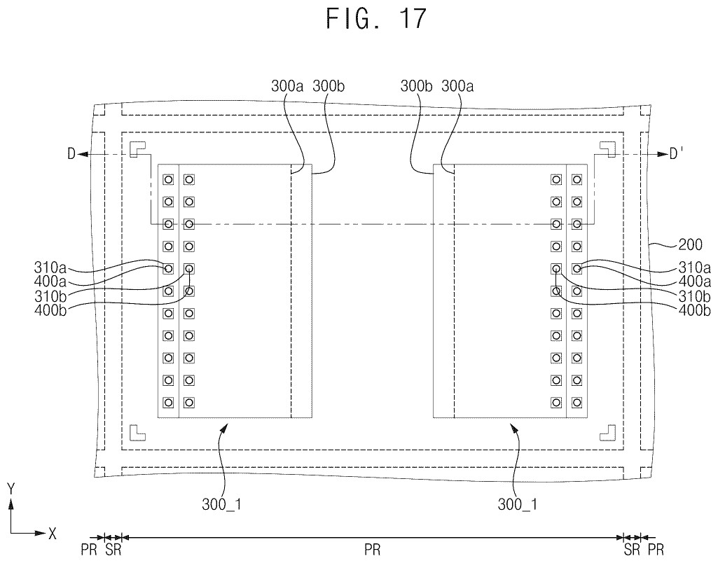

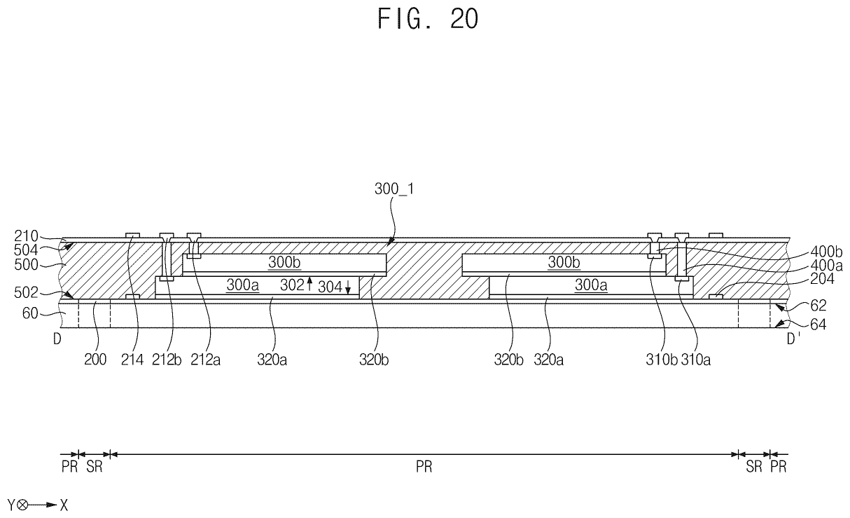

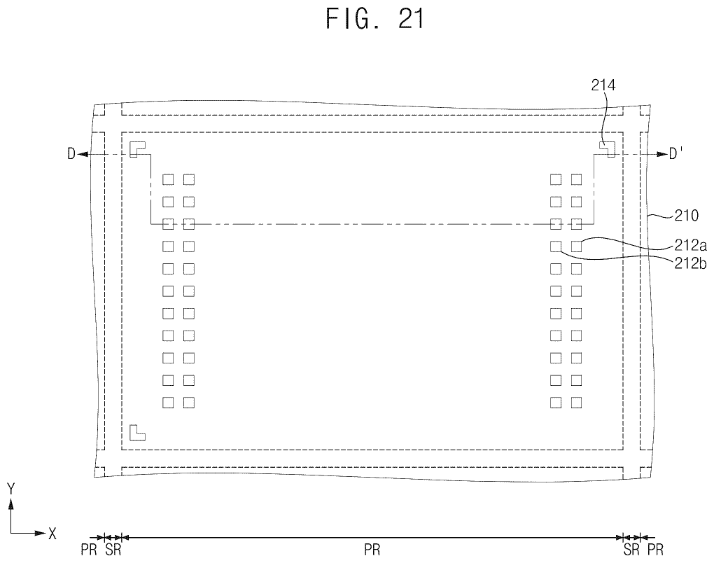

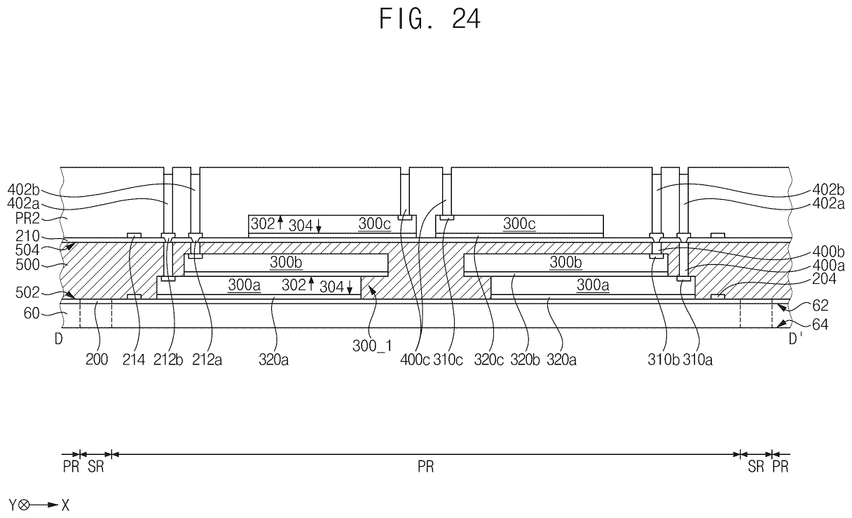

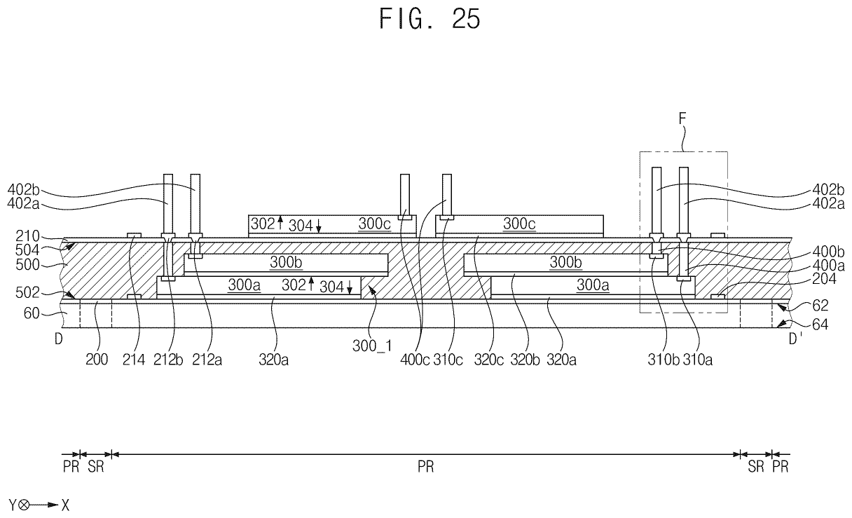

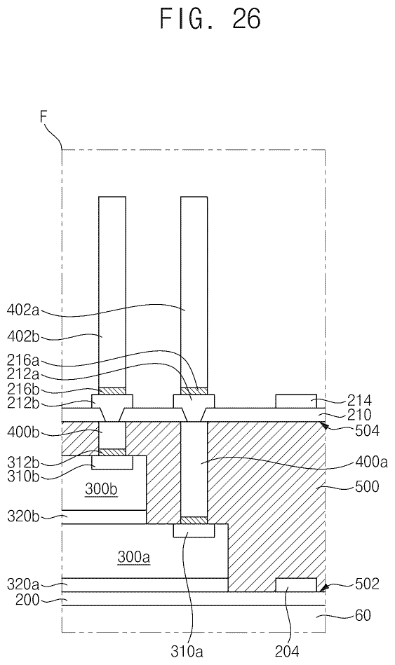

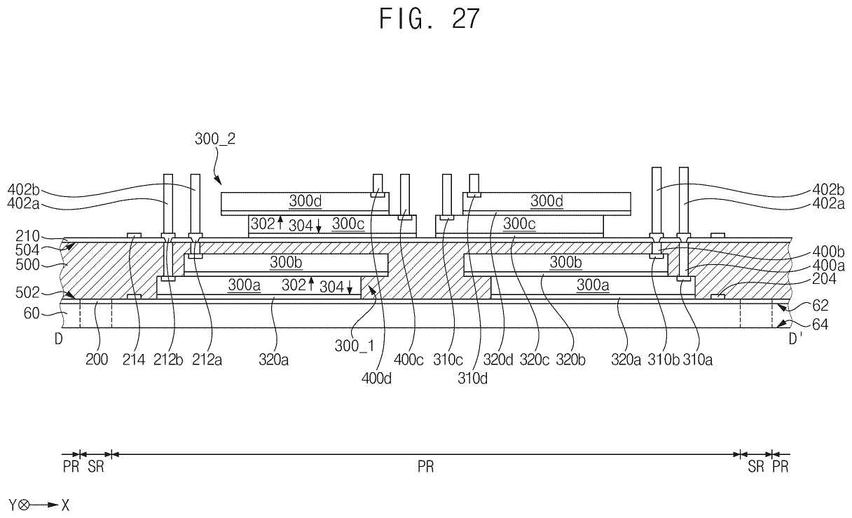

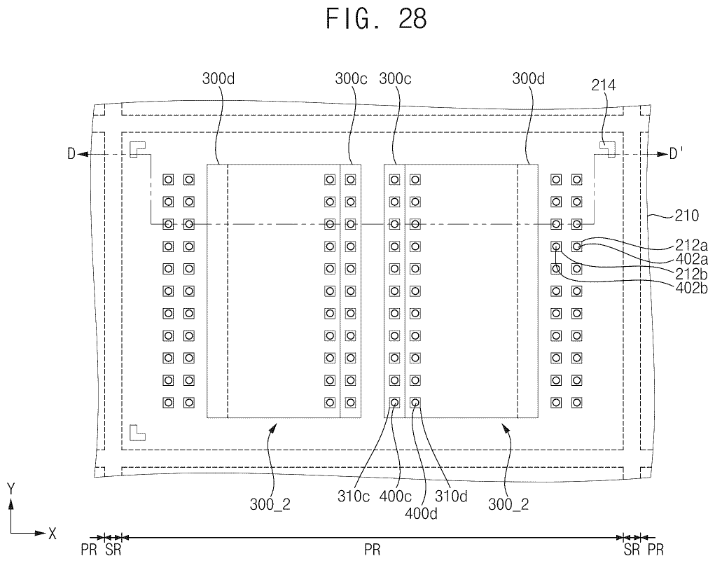

FIGS. 6 to 34 are views illustrating a method of manufacturing a semiconductor package in accordance with example embodiments. FIG. 6 is a plan view illustrating a carrier substrate having a plurality of package regions. FIGS. 7, 9, 11 to 13, 15, 16, 18 to 20, 22 to 26, and 29 to 34 are cross-sectional views illustrating a method of manufacturing a semiconductor package in accordance with example embodiments. FIG. 8 is a plan view of FIG. 7. FIG. 7 is a cross-sectional view taken along the line D-D′ in FIG. 8. FIG. 10 is a plan view of FIG. 9. FIG. 9 is a cross-sectional view taken along the line D-D′ in FIG. 10. FIG. 14 is an enlarged cross-sectional view illustrating portion ‘E’ in FIG. 13. FIG. 17 is a plan view of FIG. 16. FIG. 16 is a cross-sectional view taken along the line D-D′ in FIG. 17. FIG. 21 is a plan view of FIG. 20. FIG. 20 is a cross-sectional view taken along the line D-D′ in FIG. 21. FIG. 26 is an enlarged cross-sectional view illustrating portion ‘F’ in FIG. 25. FIG. 28 is a plan view of FIG. 27. FIG. 27 is a cross-sectional view taken along the line D-Attorney D′ in FIG. 28.

Referring to FIGS. 6 to 8, an upper redistribution wiring layer 200 may be formed on a carrier substrate 60.

In example embodiments, the carrier substrate 60 may be provided as a base substrate on which a plurality of semiconductor chips are stacked and at least one molding member and at least one redistribution wiring layer are formed to cover them. The carrier substrate 60 may have a shape corresponding to a wafer on which a semiconductor process is performed. For example, the carrier substrate 60 may include a silicon substrate such as a wafer.

The carrier substrate 60 may include a plurality of package regions PR on which the semiconductor chips are placed and a cutting region SR surrounding the package regions PR. As described below, the molding member and the redistribution wiring layer formed on the carrier substrate 60 may be cut along the cutting region SR that divides the plurality of package regions PR to be individualized.

In example embodiments, the upper redistribution wiring layer 200 may include at least one insulating layer. The insulating layer may include a polymer, a dielectric layer, etc. The insulating layer may be formed by a vapor deposition process, a spin coating process, etc. The upper redistribution wiring layer 200 may have first alignment key patterns 204. For example, an insulating layer such as PID (Photo Imageable Dielectric) may be formed on a front surface 62 of the carrier substrate 60, and a patterning process and a plating process may be formed on the insulating layer to form the first alignment key patterns 204. The first alignment key patterns 204 may include a metal material such as aluminum, copper, etc. The first alignment key patterns 204 may be formed in a peripheral region within the package region PR or the cutting region SR. As described below, a process of attaching an upper semiconductor chip may be performed using the first alignment key patterns 204.

For example, the upper redistribution wiring layer 200 may have a thickness of approximately several micrometers (um) to several tens of μm. The carrier substrate 60 may have a thickness of 600 μm to 800 μm.

Referring to FIGS. 9 to 17, a plurality of upper semiconductor chips 300_1 may be stacked on the upper redistribution wiring layer 200 on the carrier substrate 60. Each of the plurality of upper semiconductor chips 300_1 may have upper conductive pillars 400 that extend vertically on chip pads 310 respectively.

In example embodiments, two semiconductor chips 300a, 300b may be sequentially placed on the carrier substrate 60. Individual semiconductor chips cut from a wafer by a dicing process may be provided as the semiconductor chips.

As illustrated in FIGS. 9 and 10, a first semiconductor chip 300a may be attached to an upper surface of the upper redistribution wiring layer 200 on the carrier substrate 60 using an adhesive member 320a. The first semiconductor chip 300a may be attached to the upper redistribution wiring layer 200 using an adhesive film such as a die attach film (DAF) by a die attach process. For example, a thickness of the first semiconductor chip may be within a range of 35 μm to 50 μm. A thickness of the adhesive film may be within a range of 5 μm to 15 μm.

The first semiconductor chip 300a may be arranged such that a backside surface 304 opposite to the front surface 302 on which the chip pads 310a are formed faces the carrier substrate 60. The first semiconductor chip 300a may have a rectangular shape with four sides when viewed in plan view.

For example, two first semiconductor chips 300a may be attached within one package region PR. The two first semiconductor chips 300a may be arranged to be spaced apart from each other in a first direction (X direction). A first side and a third side of each of the first semiconductor chips may be arranged to be parallel to the first direction (X direction), and a second side and a fourth side of each of the first semiconductor chips may be arranged to be parallel to a second direction (Y direction) perpendicular to the first direction. The chip pads 310a may be arranged in an edge region along one side (the second side) of each of the first semiconductor chips 300a. The chip pads 310a may be arranged to be spaced apart from each other in the second direction (Y direction) on the front surface 302 of each of the first semiconductor chips 300a. It will be understood that the number, arrangement, etc. of the first semiconductor chips are provided as an example, and the present inventive concept is not limited thereto. For example, the chip pads 310a may be arranged in an edge region along the first side or the third side of each of the first semiconductor chips 300a.

The semiconductor chip may include a memory chip including memory circuits. For example, the semiconductor chip may include volatile memory devices such as SRAM devices or DRAM devices, and the like, and nonvolatile memory devices such as flash memory devices, PRAM devices, MRAM devices or RRAM devices.

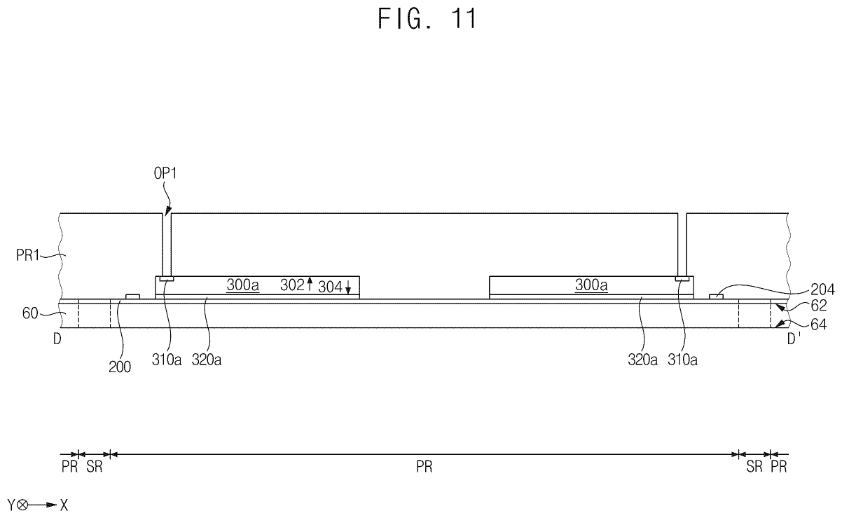

Then, as illustrated in FIGS. 11 to 14, first conductive pillars 400a as upper conductive pillars may be formed on the chip pads 310a of the first semiconductor chip 300a, respectively. The first conductive pillars 400 may be formed by a TDV (Through Dielectric Via) manufacturing method.

In particular, a seed layer may be formed on the front surface 302 of the first semiconductor chip 300a on the upper redistribution wiring layer 200, and a first photoresist pattern PR1 having first openings OP1 that exposes chip pad regions may be formed on the seed layer. Then, a plating process may be performed to fill the first openings OP1 of the first photoresist pattern PR1 with a conductive material to form the first conductive pillars 400a. Then, the first photoresist pattern PR1 may be removed and a portion of the seed layer exposed by the first conductive pillars 400a may be removed to form a seed layer pattern 312a. Accordingly, the seed layer pattern 312a may be formed on the chip pad 310a, and the first conductive pillar 400a may be formed on the seed layer pattern 312a.

The order of forming the first conductive pillars may not be limited thereto. For example, after the first conductive pillars 400a are formed on the chip pads 310a of the first semiconductor chip 300a, the first semiconductor chip 300a may be attached on the upper redistribution wiring layer 200.

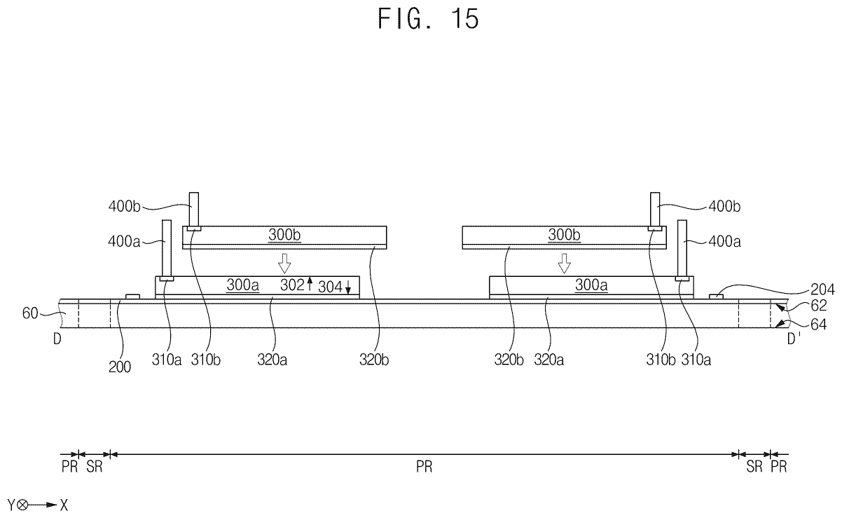

As illustrated in FIGS. 15 to 17, first, first conductive pillars 400b may be formed on chip pads 310b of a second semiconductor chip 300b, and the second semiconductor chip 300b may be attached to the first semiconductor chip 300a using an adhesive member 320b.

The first and second semiconductor chips 300a, 300b may be stacked in a cascade structure on the upper redistribution wiring layer 200. The second semiconductor chip 300b may be offset aligned on the first semiconductor chip 300a in a first horizontal direction (X direction). The second semiconductor chip 300b may be offset aligned in the first horizontal direction such that the chip pads 310a of the first semiconductor chip 300a are exposed. The first semiconductor chip 300a may include an overhang portion protruding from one side of the second semiconductor chip 300b that is stacked on the first semiconductor chip 300a. When viewed in plan view, the chip pads 310a of the first semiconductor chip 300a may be arranged to be spaced apart from each other in a second horizontal direction (Y direction) perpendicular to the first horizontal direction along one side on an upper surface, i.e., the front surface 302, of the overhang portion protruding from one side of the second semiconductor chip 300b. It will be understood that the arrangement of the second semiconductor chips is provided as an example, and the present inventive concept is not limited thereto. For example, the second semiconductor chip 300b may be aligned with an offset in the second horizontal direction (Y direction) on the first semiconductor chip 300a. At this time, the chip pads 310a of the first semiconductor chip 300a may be placed in an edge region along the first side or the third side of the first semiconductor chip 300a.

For example, two second semiconductor chips 300b may be attached within one package region PR. Accordingly, two first chip stack structures 300_1 each including the first and second semiconductor chips 300a, 300b sequentially stacked on each other may be arranged spaced apart from each other in the first direction (X direction).

It will be understood that the number, size, arrangement, etc. of the semiconductor chips are provided as an example, and the present inventive concept is not limited thereto. For example, each of the first chip stack structures 300_1 may include three or more stacked semiconductor chips. In addition, although only a few chip pads are illustrated in the figures, it will be understood that the structure, shape, and arrangement of the chip pads are provided as an example, and the present inventive concept is not limited thereto.

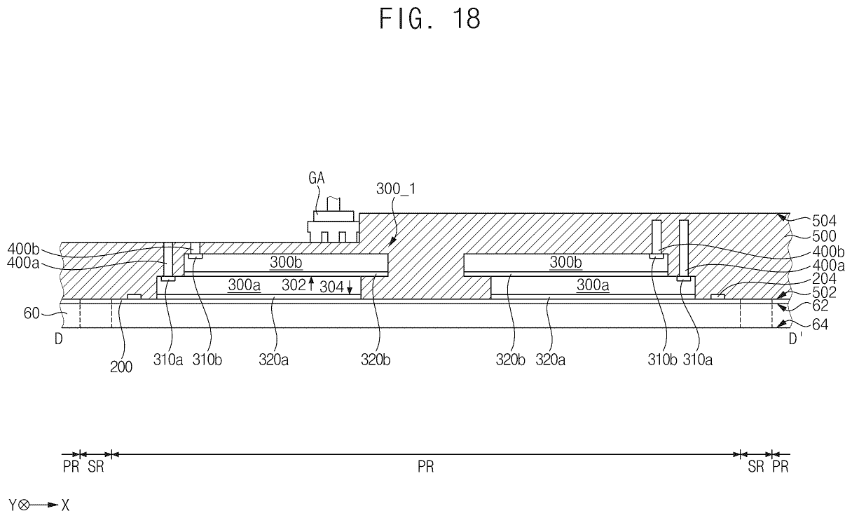

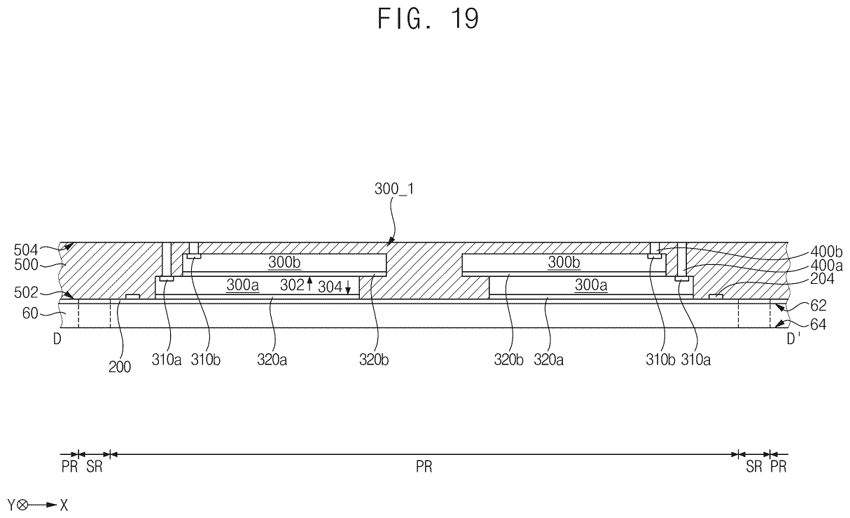

Referring to FIGS. 18 and 19, an upper molding member 500 may be formed on the upper redistribution wiring layer 200 on the carrier substrate 60 to cover the plurality of upper semiconductor chips 300_1.

In example embodiments, a first sealing material may be formed on the upper surface of the upper redistribution wiring layer 200 to cover the plurality of upper semiconductor chips 300_1 and the first conductive pillars 400a, 400b, and an upper portion of the first sealing material may be partially removed to have a desired height using a grinding apparatus GA, to form the upper molding member 500. At this time, end portions of the first conductive pillars 400a, 400b may be partially removed together.

The upper molding member 500 may be formed to completely cover the plurality of upper semiconductor chips 300_1. The upper molding member 500 may have a first surface 504 and a second surface 502 opposite to the first surface 504. The second surface 502 of the upper molding member 500 may contact the upper redistribution wiring layer 200. End portions of the first conductive pillars 400a, 400b may be exposed from the first surface 504 of the upper molding member 500.

For example, the first molding member 500 may include a thermosetting resin, for example, epoxy mold compound (EMC). The upper molding member 500 may include fillers and an epoxy resin that acts as a binder for the fillers.

Referring to FIGS. 20 and 21, an intermediate redistribution wiring layer 210 may be formed on the first surface 504 of the upper molding member 500.

In example embodiments, the intermediate redistribution wiring layer 210 may include at least one insulating layer. The insulating layer may include a polymer, a dielectric layer, or the like. The insulating layer may be formed by a vapor deposition process, a spin coating process, etc. The intermediate redistribution wiring layer 210 may have connection pads 212a, 212b that are connected to the end portions of the first conductive pillars 400a, 400b exposed from the first surface 504 of the upper molding member 500. The intermediate redistribution wiring layer 210 may have second align key patterns 214. For example, an insulating layer such as PID (Photo Imageable Dielectric) may be formed on the first surface 504 of the upper molding member 500, and a patterning process and a plating process may be formed on the insulating layer to form the connection pads 212a, 212b and the second align key patterns 214. The connection pads 212a, 212b and the second align key patterns 214 may include a metal material such as copper. The second align key patterns 214 may be formed in a peripheral area within the package region PR. As described below, a process of attaching a lower semiconductor chip may be performed using the second align key patterns 214.

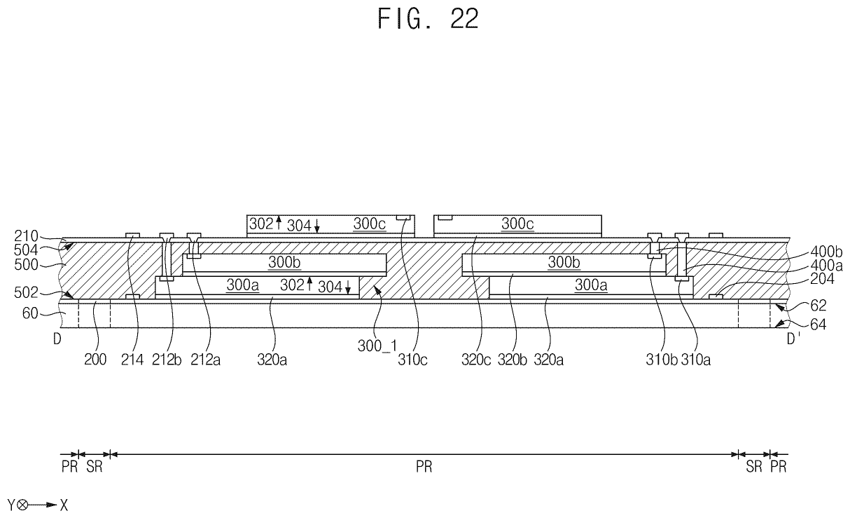

Referring to FIGS. 22 to 28, processes the same as or similar to the processes described with reference to FIGS. 7 to 14 may be performed to stack a plurality of lower semiconductor chips 300_2 on the intermediate redistribution wiring layer 210 on the upper molding member 500. Each of the plurality of lower semiconductor chips 300_2 may have upper conductive pillars 400 that extend vertically on chip pads 310 respectively.

In example embodiments, two semiconductor chips 300c, 300c may be sequentially placed on the intermediate redistribution wiring layer 210 on the upper molding member 500. Individual semiconductor chips cut from a wafer by a dicing process may be provided as the semiconductor chips.

As illustrated in FIG. 22, a third semiconductor chip 300c may be attached to the intermediate redistribution wiring layer 210 on the upper molding member 500 using an adhesive member 320c. The third semiconductor chip 300c may be attached to the intermediate redistribution wiring layer 210 by using an adhesive film such as a die attach film (DAF) by a die attach process.

The third semiconductor chip 300c may be arranged such that a backside surface 304 opposite to a front surface 302 on which chip pads 310c are formed faces the intermediate redistribution wiring layer 210. The third semiconductor chip 200c may have a rectangular shape with four sides when viewed in plan view.

For example, two third semiconductor chips 300c may be attached within one package region PR. The two third semiconductor chips 300c may be arranged to be spaced apart from each other in the first direction (X direction). A first side and a third side of each of the third semiconductor chips may be arranged to be parallel to the first direction (X direction), and a second side and a fourth side of each of the third semiconductor chips may be arranged to be parallel to the second direction (Y direction). The chip pads 310c may be arranged in an edge region along one side (the second side) of each of the third semiconductor chips 300c. The chip pads 310c may be arranged to be spaced apart from each other in the second direction (Y direction) on the front surface 302 of each of the third semiconductor chips 300c. It will be understood that the number, arrangement, etc. of the third semiconductor chips are provided as an example, and the present inventive concept is not limited thereto. For example, the chip pads 310c may be arranged in an edge region along the first side or the third side of each of the third semiconductor chips 300c.

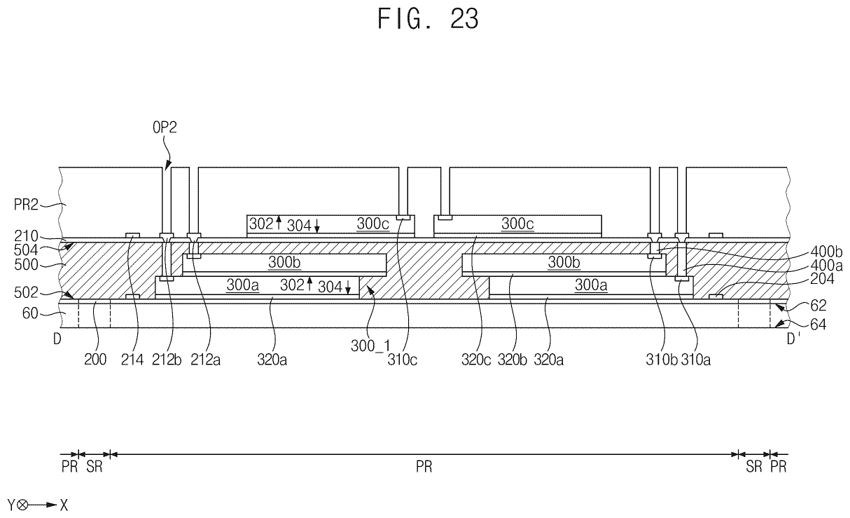

Then, as illustrated in FIGS. 23 to 26, second conductive pillars 400c as lower conductive pillars may be formed on the chip pads 310c of the third semiconductor chip 300c, respectively. In addition, conductive connection pillars 402a, 402b for electrical connection with the first conductive pillars 400a, 400b may be formed on the connection pads 212a, 212b of the intermediate redistribution wiring layer 210, respectively.

In particular, a seed layer may be formed on the front surface 302 of the third semiconductor chip 300c on the intermediate redistribution wiring layer 210, and a second photoresist pattern PR2 having second openings OP2 that expose chip pad regions and connection pad regions may be formed on the seed layer. Then, a plating process may be performed to fill the second openings OP2 of the second photoresist pattern PR2 with a conductive material to form the second conductive pillars 400c and the conductive connection pillars 402a, 402b. Then, the second photoresist pattern PR2 may be removed, and a portion of the seed layer exposed by the second conductive pillars 400c may be removed to form a seed layer pattern 312c. In addition, a portion of the seed layer exposed by the conductive connection pillars 402a, 402b may be removed to form seed layer patterns 216a, 216b (see FIG. 27). Accordingly, the seed layer pattern 312c may be formed on the chip pad 310c of the third semiconductor chip 300c, and the second conductive pillar 400c may be formed on the seed layer pattern 312c. In addition, the seed layer patterns 216a, 216b may be formed on the connection pads 212a, 212b of the intermediate redistribution wiring layer 210, respectively, and the conductive connection pillars 402a, 402b may be formed on the seed layer patterns 216a, 216b, respectively.

The order of forming the second conductive pillars may not be limited thereto. For example, after the second conductive pillars 400c are formed on the chip pads 310c of the third semiconductor chip 300c, the third semiconductor chip 300c may be attached to the intermediate redistribution wiring layer 210. At this time, the conductive connection pillars 402a, 402b may be formed on the intermediate redistribution wiring layer 210 before attaching the third semiconductor chip 300c to the intermediate redistribution wiring layer 210.

As illustrated in FIGS. 27 and 28, first, second conductive pillars 400d may be formed on chip pads 310d of a fourth semiconductor chip 300d, and the fourth semiconductor chip 300d may be attached to the third semiconductor chip 300c using an adhesive member 320d.

The third and fourth semiconductor chips 300c, 300d may be stacked in a cascade structure on the intermediate redistribution wiring layer 210. The fourth semiconductor chip 300d may be offset aligned on the third semiconductor chip 300b in a first horizontal direction (X direction). The fourth semiconductor chip 300d may be offset aligned in the first horizontal direction such that the chip pads 310c of the third semiconductor chip 300c are exposed. The third semiconductor chip 300c may include an overhang portion protruding from one side of the fourth semiconductor chip 300d that is stacked on the third semiconductor chip 300c. When viewed in plan view, the chip pads 310c of the third semiconductor chip 300c may be spaced apart from each other in a second horizontal direction (Y direction) perpendicular to the first horizontal direction along one side on an upper surface, i.e., the front surface 302, of the overhang portion protruding from one side of the fourth semiconductor chip 300d. It will be understood that the arrangement of the fourth semiconductor chip is provided as an example, and the present inventive concept is not limited thereto. For example, the fourth semiconductor chip 300d may be aligned with an offset in the second horizontal direction (Y direction) on the third semiconductor chip 300c. At this time, the chip pads 310c of the third semiconductor chip 300c may be placed in an edge region along the first side or the third side of the third semiconductor chip 300c.

For example, two fourth semiconductor chips 300d may be attached within one package region PR. Accordingly, two second chip stack structures 300_2 each including the third and fourth semiconductor chips 300c, 300d sequentially stacked on each other may be arranged spaced apart from each other in the first direction (X direction).

It will be understood that the number, size, arrangement, etc. of the semiconductor chips are provided as an example, and the present inventive concept is not limited thereto. For example, each of the second chip stack structures 300_2 may include three or more stacked semiconductor chips. In addition, although only a few chip pads are illustrated in the figures, it will be understood that the structure, shape, and arrangement of the chip pads are provided as an example, and the present inventive concept is not limited thereto.

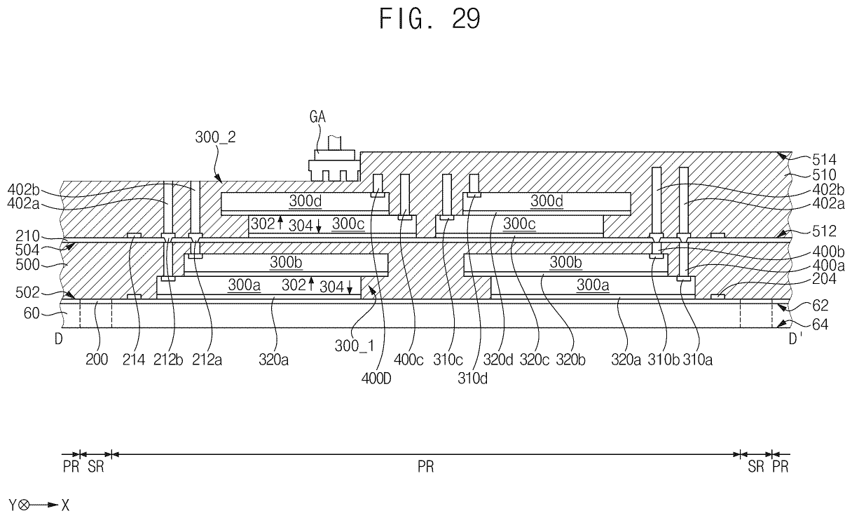

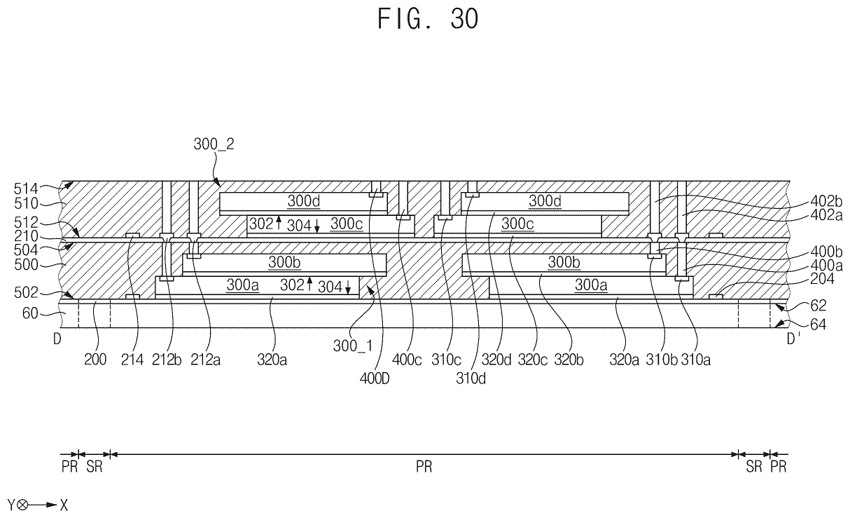

Referring to FIGS. 29 and 30, a lower molding member 510 may be formed on the intermediate redistribution wiring layer 210 on the upper molding member 500 to cover the plurality of lower semiconductor chips 300_2.

In example embodiments, a second molding material may be formed on the upper surface of the intermediate redistribution wiring layer 210 to cover the plurality of lower semiconductor chips 300_2, the second conductive pillars 400c, 400d and the conductive connection pillars 402a, 402b, and an upper portion of the second molding material may be partially removed to have a desired height using a grinding apparatus GA, to form the lower molding member 510. At this time, end portions of the second conductive pillars 400c, 400d and the conductive connection pillars 402a, 402b may be partially removed together.

The lower molding member 510 may be formed to completely cover the plurality of lower semiconductor chips 300_2. The lower molding member 510 may have a first surface 514 and a second surface 512 opposite to the first surface 514. The second surface 512 of the lower molding member 510 may be in contact with the intermediate redistribution wiring layer 210. End portions of the second conductive pillars 400c, 400d and the conductive connecting pillars 402a, 402b may be exposed from the first surface 514 of the lower molding member 510.

For example, the second molding member 500 may include a thermosetting resin, for example, epoxy mold compound (EMC). The lower molding member 510 may include fillers and an epoxy resin that acts as a binder for the fillers.

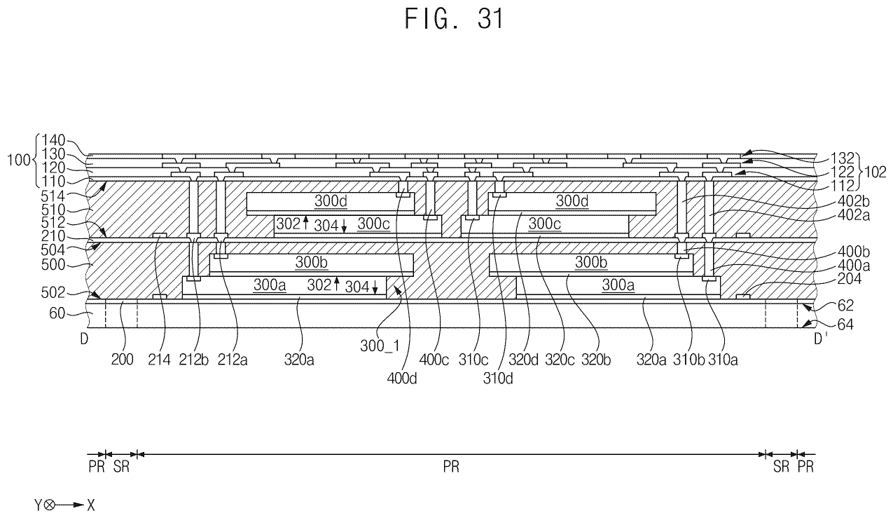

Referring to FIG. 31, a lower redistribution wiring layer 100 may be formed on the first surface 514 of the lower molding member 510. The lower redistribution wiring layer 100 may have redistribution wirings 102 electrically connected to the first and second conductive pillars 400a, 400b, 400c, 400d and the conductive connection pillars 402a, 402b.

In example embodiments, after a first lower insulating layer 110 is formed on the first surface 514 of the lower molding member 510, the first lower insulating layer 110 may be patterned to form first openings. The first openings may expose an end portion of each of the second conductive pillars 400c, 400d and the conductive connection pillars 402a, 402b. The first lower insulating layer 110 may include a polymer, a dielectric layer, etc. The first lower insulating layer 110 may be formed by a vapor deposition process, a spin coating process, etc.

Then, a seed layer may be formed on the exposed end portions of the second conductive pillars 400c, 400d and the conductive connecting pillars 402a, 402b and within the first openings, and then the seed layer may be patterned and an electrolytic plating process may be performed to form the first lower redistribution wirings 112. Accordingly, at least some of the first lower redistribution wirings 112 may be electrically connected to the second conductive pillars 400c, 400d and the conductive connection pillars 402a, 402b through the first openings. The first lower redistribution wirings may include aluminum (Al), copper (Cu), tin (Sn), nickel (Ni), gold (Au), platinum (Pt), or an alloy thereof.

Similarly, after a second lower insulating layer 120 is formed on the first lower insulating layer 110, the second lower insulating layer 120 may be patterned to form second openings that expose the first lower redistribution wirings 112, respectively. Then, second lower redistribution wirings 122 may be formed on the second lower insulating layer 120 to be electrically connected to the first lower redistribution wirings 112 through the second openings.

Similarly, after a third lower insulating layer 130 is formed on the second lower insulating layer 120, the third lower insulating layer 130 may be patterned to form third openings that expose the second lower redistribution wirings 122, respectively. Then, third lower redistribution wirings 132 may be formed on the third lower insulating layer 130 to be electrically connected to the second lower redistribution wirings 122 through the third openings.

Then, a fourth lower insulating layer 140 may be formed on the third lower insulating layer 130 to cover the third lower redistribution wirings 132. The fourth lower insulating layer 140 may serve as a passivation layer. Then, the fourth lower insulating layer 140 may be partially removed by a via formation process to form openings 141 that expose portions of the third lower redistribution wirings 132. A lower bonding pad (not illustrated) such as UBM may be formed on the third lower redistribution wirings 132 exposed by the fourth lower insulating layer 140 by a plating process.

Accordingly, the lower redistribution wiring layer 100 having the redistribution wirings 102 as a front redistribution layer (FRDL) may be formed on the lower molding member 510. The lower redistribution wiring layer 100 may include the first to fourth lower insulating layers 110, 120, 130, 140 stacked on one another and the redistribution wirings 102 in the first to fourth lower insulating layers 110, 120, 130, 140. The redistribution wirings 102 may include the first, second, and third lower redistribution wirings 112, 122, 132.

It will be understood that the number, size, arrangement, etc. of the lower insulating layers and the redistribution wirings of the lower redistribution wiring layer are provided as an example, and the present inventive concept is not limited thereto.

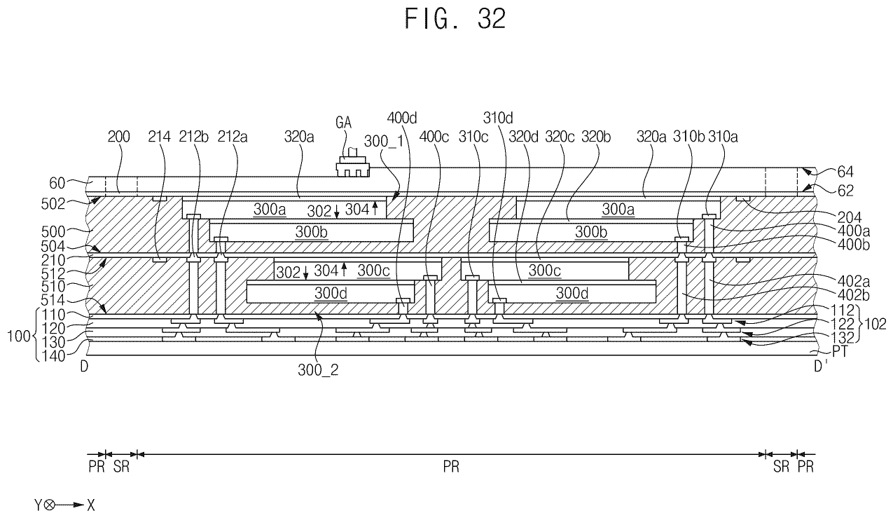

Referring to FIGS. 32 to 34, the carrier substrate 60a may be ground to form a marking layer 600 having a desired thickness, and a marking pattern 610 may be formed in an outer surface of the marking layer 600.

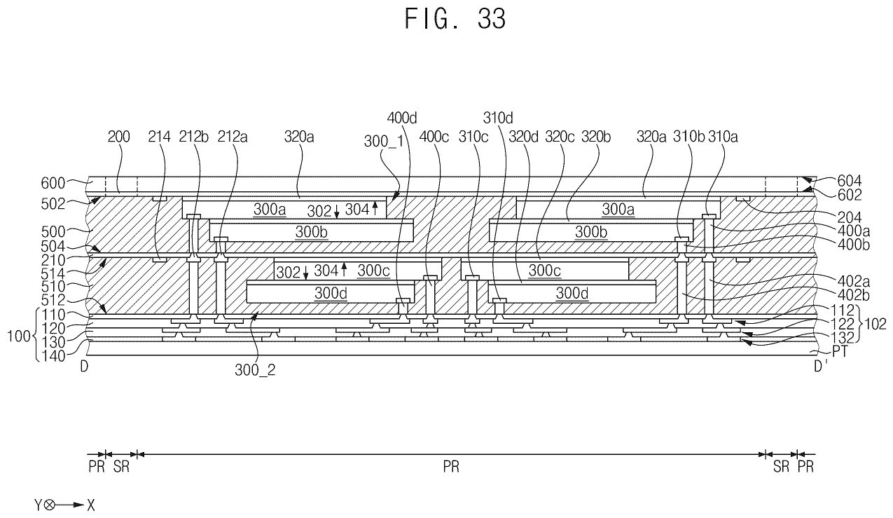

As illustrated in FIGS. 32 and 33, a protective tape PT may be attached on the lower redistribution wiring layer 100 to cover the lower bonding pads, the structure of FIG. 31 may be turned over, and a backside surface 64 of the carrier substrate 60 may be ground to form the marking layer 600 of a desired thickness.

For example, the backside surface 64 of the carrier substrate 60 may be partially removed by a grinding apparatus GA. The thickness of the marking layer 600 may be within a range of 20 μm to 100 μm. The marking layer 600 may be a silicon layer including silicon. The marking layer 600 including silicon may have a thermal conductivity of about 139.4 W/mK. The thermal conductivity of the upper and lower molding members 500, 510 may be within a range of 1.8 W/mK to 3 W/mK. Accordingly, the marking layer 600 having high thermal conductivity may be overlapped to cover the front surfaces of the upper and lower molding members 500, 510, thereby improving the heat dissipation performance of the package. In addition, since the marking layer 600 including silicon has relatively high strength, warpage of the package may be prevented.

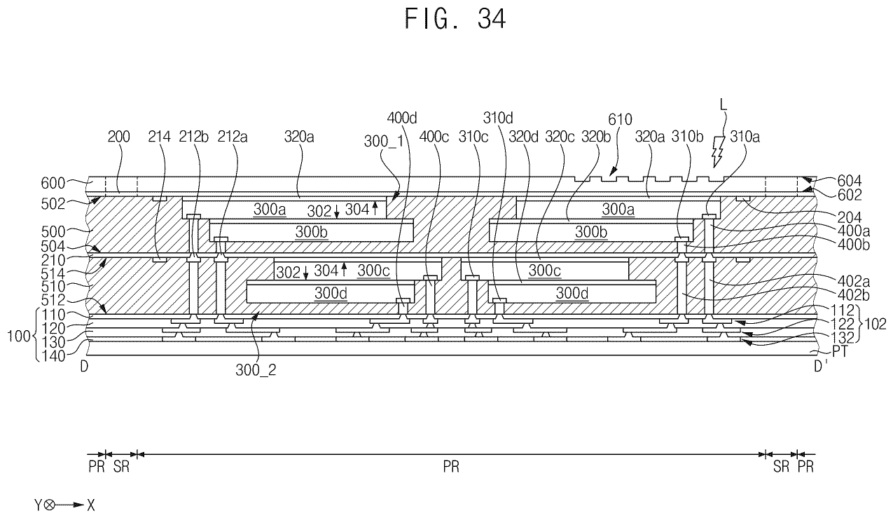

As illustrated in FIG. 34, the marking pattern 610 may be formed by irradiating a laser L on the outer surface 604 of the marking layer 600. The marking pattern 610 may be formed by a laser processing device. The laser processing device may include an excimer laser device, a diode pumped solid state laser device, etc. The laser may have a wavelength of 355 nm or 532 nm.

The laser processing device may include a scanner optical system to form an engraved pattern in the outer surface 604 of the marking layer 600. The engraved pattern may indicate a manufacturer, a manufacturing date, a serial number, etc. The laser may form openings in a backside surface 610 of the marking layer 610, and the engraved pattern may be defined by the openings. The openings may include a groove having a preset depth.

According to related arts, after a seed layer, a release film, and a marking layer are formed on a carrier substrate, semiconductor chips, a molding member, and a redistribution wiring layer may be formed, and then, after the carrier substrate, the seed layer, and the release film are removed from the marking layer, a marking pattern may be formed in the marking layer. However, according to example embodiments, without forming a separate marking layer, a silicon layer may be formed by removing the backside surface of the silicon carrier substrate, and then the silicon layer may be utilized as the marking layer. Accordingly, the manufacturing process may be simplified and costs may be reduced.

Then, the protective tape PT may be removed, external connection members 160 (see FIG. 1) may be formed on the lower bonding pads of the lower redistribution wiring layer 100, and then, the lower redistribution wiring layer 100, the middle redistribution wiring layer 210, the upper redistribution wiring layer 200, the upper and lower molding members 500, 510, and the marking layer 600 may be cut along the cutting region SR to complete the semiconductor package 10 of FIG. 1.

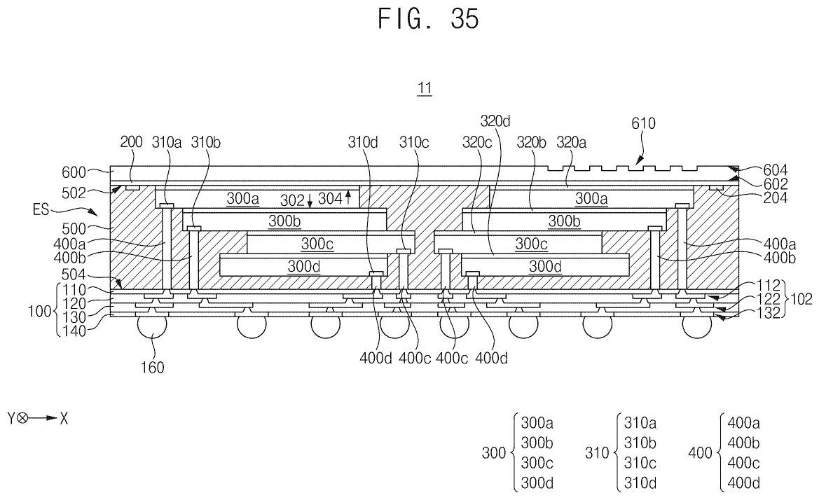

FIG. 35 is a cross-sectional view illustrating a semiconductor package in accordance with example embodiments. The semiconductor package may be substantially the same as or similar to the semiconductor package described with reference to FIG. 1, except for configurations of semiconductor chips within one encapsulation structure. Thus, same reference numerals will be used to refer to the same or like elements and any further repetitive explanation concerning the above elements will be omitted.

Referring to FIG. 35, a semiconductor package 11 may include a lower redistribution wiring layer 100, an encapsulation structure ES disposed on the lower redistribution wiring layer 100, and a marking layer 600 provided on the encapsulation structure ES. In addition, the semiconductor package 10 may further include external connection members 160 disposed on an outer surface of the lower redistribution wiring layer 100.

In example embodiments, the encapsulation structure ES may include a molding member 500, a plurality of semiconductor chips 300 disposed within the molding member 500, a plurality of conductive pillars 400 as vertical conductive structures extending in a vertical direction from chip pads 310 of the plurality of semiconductor chips 300 within the molding member 500, and an upper redistribution wiring layer 200 provided on the molding member 500.

The molding member 500 may have a first surface 504 that contacts the lower redistribution wiring layer 100 and a second surface 502 that is opposite to the first surface 504. For example, the molding member 500 may include a thermosetting resin, for example, epoxy mold compound EMC.

The plurality of semiconductor chips 300 may include first, second, third, and fourth semiconductor chips 300a, 300b, 300c, 300d that are sequentially stacked within the molding member 500. The plurality of semiconductor chips 300 may be arranged such that a front surface 302 on which chip pads 310a, 310b, 310c, 310d are formed faces the lower redistribution wiring layer 100. Each of the semiconductor chips 300 may have a rectangular shape having four sides when viewed in plan view. A first side and a third side of each of the semiconductor chips 300 may be arranged to be parallel to a first direction (X direction), and a second side and a fourth side of each of the semiconductor chips may be arranged to be parallel to a second direction (Y direction) perpendicular to the first direction. The chip pads 310a, 310b, 310c, 310d may be arranged in an edge region along one side (second side) of each of the semiconductor chips 300. The chip pads 310, 310b, 310c, 310d may be arranged to be spaced apart from each other in the second direction (Y direction) on the front surface 302 of each of the first, second, third, and fourth semiconductor chips 300a, 300b, 300c, 300d. It will be understood that the number, arrangement, etc. of the semiconductor chips are provided as an example, and the present inventive concept is not limited thereto. For example, the chip pads 310a, 310b, 310c, 310d may be arranged in an edge region along the first side or the third side of each of the first, second, third, and fourth semiconductor chips 300a, 300b, 300c, 300d.

In particular, the first, second, third and fourth semiconductor chips 300a, 300b, 300c, 300d may be stacked in a cascade manner on the upper redistribution wiring layer 200. The second semiconductor chip 300b may be offset aligned in a first horizontal direction (X direction) on the first semiconductor chip 300a. The second semiconductor chip 300b may be offset aligned in the first horizontal direction (X direction) such that the chip pads 310a of the first semiconductor chip 300a are exposed. The third semiconductor chip 300c may be offset aligned in the first horizontal direction (X direction) on the second semiconductor chip 300b. The third semiconductor chip 300c may be offset aligned in the first horizontal direction (X direction) such that the chip pads 310b of the second semiconductor chip 300b are exposed. The fourth semiconductor chip 300d may be offset aligned on the third semiconductor chip 300c in an opposite direction to the first horizontal direction (X direction). The fourth semiconductor chip 300d may be offset aligned on the third semiconductor chip 300c in an opposite direction to the first horizontal direction (X direction) such that the chip pads 310c of the third semiconductor chip 300c are exposed.

For example, two first semiconductor chips 300a may be attached within one package region PR. The two first semiconductor chips 300a may be spaced apart from each other in the first direction (X direction). Two second semiconductor chips 300b may be respectively arranged on the two first semiconductor chips 300a. Two third semiconductor chips 300c may be respectively arranged on two second semiconductor chips 300b. Two fourth semiconductor chips 300d may be respectively arranged on two third semiconductor chips 300c. Accordingly, two stack structures 300 each including sequentially stacked first, second, third, and fourth semiconductor chips 300a, 300b, 300c, 300d may be arranged to be spaced apart from each other in the first direction (X direction).

It will be understood that the number, size, arrangement, etc. of the semiconductor chips are provided as an example, and the present inventive concept is not limited thereto. For example, each of the chip stack structures may include five or more stacked semiconductor chips. In addition, although only a few chip pads are illustrated in the figures, it will be understood that the structure, shape, and arrangement of the chip pads are provided as an example, and the present inventive concept is not limited thereto.

In example embodiments, the conductive pillars 400a, 400b, 400c, 400d may extend vertically on the chip pads 310a, 310b, 310c, 310d of the first, second, third, and fourth semiconductor chips 300a, 300b, 300c, 300d within the molding member 500, respectively. When viewed from bottom view, the conductive pillars 400a, 400b, 400c, 400d may be positioned within an area where the first, second, third, and fourth semiconductor chips 300a, 300b, 300c, 300d are arranged.

The conductive pillars 400a, 400b, 400c, 400d may be formed by a TDV (Through Dielectric Via) manufacturing method. The conductive pillars 400a, 400b, 400c, 400d may be formed by a plating process. Seed layer patterns may be provided on the chip pads 310a, 310b, 310c, 310d of the first, second, third, and fourth semiconductor chips 300a, 300b, 300c, 300d, respectively, and the conductive pillars 400a, 400b, 400c, 400d may be provided on the seed layer patterns, respectively. The conductive pillars 400a, 400b, 400c, 400d may include a metal material such as copper (Cu).

The upper redistribution wiring layer 200 may include at least one insulating layer. The insulating layer may include a polymer, a dielectric layer, etc. Alignment key patterns 204 may be provided on a lower surface of the upper redistribution wiring layer 200. The process of attaching the semiconductor chips may be performed using the alignment key patterns 204.

In example embodiments, the marking layer 600 may be provided on the upper redistribution wiring layer 200. A marking pattern 610 may be provided in an outer surface of the marking layer 600. The marking pattern 610 may include an engraved pattern defined by a plurality of openings formed by irradiating a laser on the outer surface of the marking layer 600. The opening may include a groove having a preset depth. The engraved pattern may indicate a manufacturer, a manufacturing date, a serial number, etc.

For example, a thickness of the marking layer 600 may be within a range of 20 μm to 100 μm. The marking layer 600 may be a silicon layer including silicon. The marking layer 600 including silicon may have a thermal conductivity of about 139.4 W/mK. The thermal conductivity of the molding member 500 may be in the range of 1.8 W/mK to 3 W/mK.

In example embodiments, the external connection members 160 may be disposed on a lower surface of the lower redistribution wiring layer 100. For example, each of the external connection members 160 may include a conductive bump. The semiconductor package 10 may be mounted on a lower package, an interposer, a package substrate, etc. via the external connection members 160.

Hereinafter, a method for manufacturing the semiconductor package of FIG. 35 will be described.

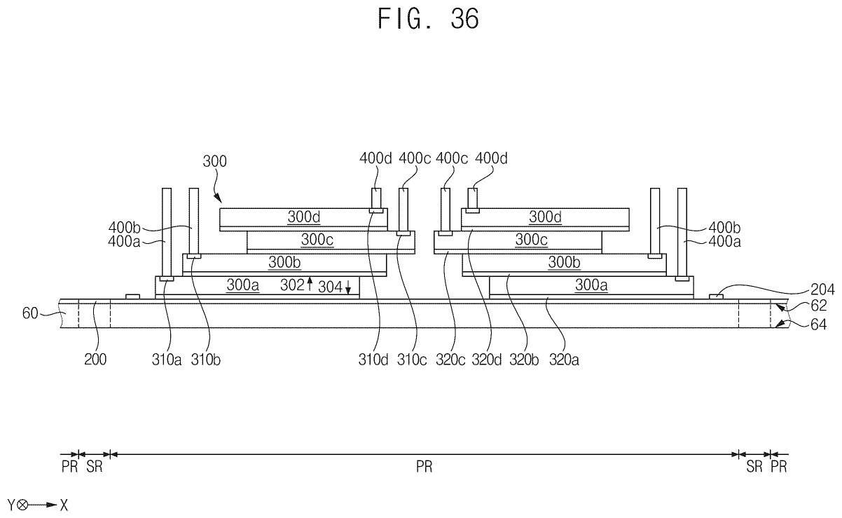

FIGS. 36 to 42 are cross-sectional views illustrating a method of manufacturing a semiconductor package in accordance with example embodiments.

Referring to FIG. 36, processes the same as or similar to the processes described with reference to FIGS. 9 to 17 may be performed to form an upper redistribution wiring layer 200 on a carrier substrate 60, and a plurality of semiconductor chips 300 may be stacked on the upper redistribution wiring layer 200. Each of the plurality of semiconductor chips 300 may have conductive pillars 400 extending vertically on chip pads 310.

First, an insulating layer such as PID (Photo Imageable Dielectric) may be formed on a front surface 62 of the carrier substrate 60, and a patterning process and a plating process may be formed on the insulating layer to form alignment key patterns 204. The align key patterns 204 may include a metal material such as aluminum, copper, etc. The align key patterns 204 may be formed in a peripheral region within a package region PR or within a cutting region SR. As described below, a process of attaching semiconductor chips may be performed using the align key patterns 204.

Then, four semiconductor chips 300a, 300b, 300c, 300d may be sequentially stacked on the upper redistribution wiring layer 200 on the carrier substrate 60. The semiconductor chips 300a, 300b, 300c, 300d may be sequentially attached on the upper redistribution wiring layer 200 on the carrier substrate 60 using adhesive members 320a, 320b, 320c, 320d.

The semiconductor chips 300a, 300b, 300c, 300d may be sequentially attached on the upper redistribution wiring layer 200 on the carrier substrate 60 using adhesive films such as die attach film (DAF) by a die attach process. The semiconductor chips 300a, 300b, 300c, 300d may be arranged such that a backside surface 304 opposite to a front surface 302 on which chip pads 310a, 310b, 310c, 310d are formed faces the carrier substrate 60. Each of the semiconductor chips 300a, 300b, 300c, 300d may have a rectangular shape with four sides when viewed in plan view. The chip pads 310 may be arranged in an edge region along one side of each of the semiconductor chips 300a, 300b, 300c, 300d.

In example embodiments, first, second, third, and fourth semiconductor chips 300a, 300b, 300c, 300d may be stacked in a cascade manner on the upper redistribution wiring layer 200 on the carrier substrate 60. The second semiconductor chip 300b may be offset aligned in a first horizontal direction (X direction) on the first semiconductor chip 300a. The second semiconductor chip 300b may be offset aligned in the first horizontal direction (X direction) such that the chip pads 310a of the first semiconductor chip 300a are exposed. The third semiconductor chip 300c may be offset aligned in the first horizontal direction (X direction) on the second semiconductor chip 300b. The third semiconductor chip 300c may be offset aligned in the first horizontal direction (X direction) such that the chip pads 310b of the second semiconductor chip 300b are exposed. The fourth semiconductor chip 300d may be offset aligned on the third semiconductor chip 300c in an opposite direction to the first horizontal direction (X direction). The fourth semiconductor chip 300d may be offset aligned in the opposite direction to the first horizontal direction (X direction) such that the chip pads 310c of the third semiconductor chip 300c are exposed.

Each of the first, second, and third semiconductor chips 300a, 300b, 300c, 300d may include an overhang portion protruding from one side of each of the overlying second, third, and fourth semiconductor chips 300b, 300c, 300d. When viewed in plan view, the chip pads 310a of the first semiconductor chip 300a may be arranged on an upper surface, i.e., the front surface 302, of the overhang portions protruding from one side of the second, third and fourth semiconductor chips 300b, 300c, 300d to be spaced apart from each other along a second horizontal direction (Y direction) perpendicular to the first horizontal direction. When viewed in plan view, the chip pads 310b of the second semiconductor chip 300b may be arranged on an upper surface, i.e., the front surface 302, of the overhang portions protruding from one side of the third and fourth semiconductor chips 300d to be spaced apart from each other along the second horizontal direction (Y direction). When viewed in plan view, the chip pads 310c of the third semiconductor chip 300c may be arranged on an upper surface, i.e., the front surface 302, of the overhang portion protruding from one side of the fourth semiconductor chip 300d to be spaced apart from each other along the second horizontal direction (Y direction).

For example, two first semiconductor chips 300a may be attached within one package region PR. The two first semiconductor chips 300a may be arranged to be spaced apart from each other in a first direction (X direction). Two second semiconductor chips 300b may be respectively disposed on the two first semiconductor chips 300a. Two third semiconductor chips 300c may be respectively disposed on the two second semiconductor chips 300b. Two fourth semiconductor chips 300d may be respectively disposed on the two third semiconductor chips 300c. Accordingly, two stack structures 300 each including sequentially stacked first, second, third and fourth semiconductor chips 300a, 300b, 300c, 300d may be arranged to be spaced apart from each other in the first direction (X direction).

It will be understood that the number, size, arrangement, etc. of the semiconductor chips are provided as examples, and the present inventive concept is not limited thereto. For example, each of the chip stack structures may include five or more stacked semiconductor chips. In addition, although only a few chip pads are illustrated in the figures, it will be understood that the structure, shape and arrangement of the chip pads are provided as examples, and the present inventive concept is not limited thereto.

Then, conductive pillars 400a, 400b, 400c, 400d may be formed on the chip pads 310a, 310b, 310c, 310d of first, second, third, and fourth semiconductor chips 300a, 300b, 300c, 300d, respectively. The conductive pillars 400 may be formed by a TDV (Through Dielectric Via) manufacturing method. The conductive pillars 400a, 400b, 400c, 400d may be formed by a plating process. Seed layer patterns may be formed on the chip pads 310a, 310b, 310c, 310d of the first, second, third, and fourth semiconductor chips 300a, 300b, 300c, 300d, respectively, and the conductive pillars 400a, 400b, 400c, 400d may be formed on the seed layer patterns, respectively.

The order of forming the conductive pillars may not be limited thereto. For example, after the conductive pillars 400a, 400b, 400c, 400d are formed on the chip pads 310a, 310b, 310c, 310d of first, second, third, and fourth semiconductor chips 300a, 300b, 300c, 300d, the first, second, third, and fourth semiconductor chips 300a, 300b, 300c, 300d may be sequentially attached on the upper redistribution wiring layer 200.

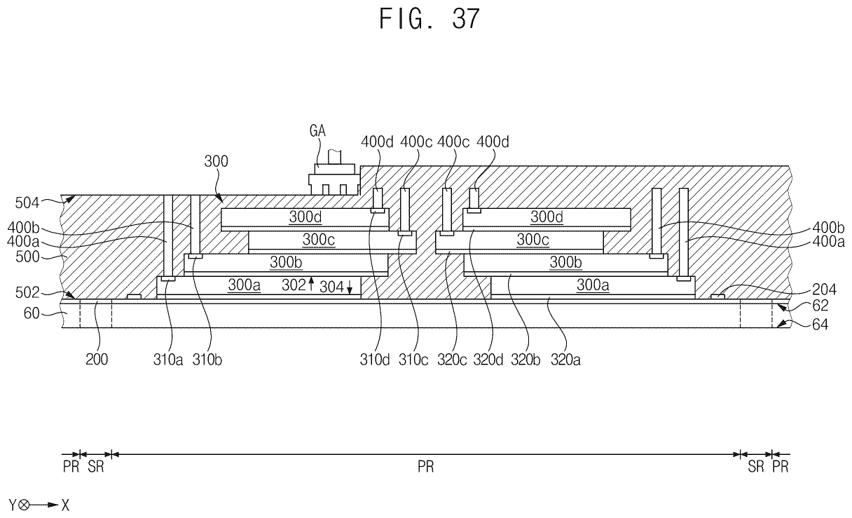

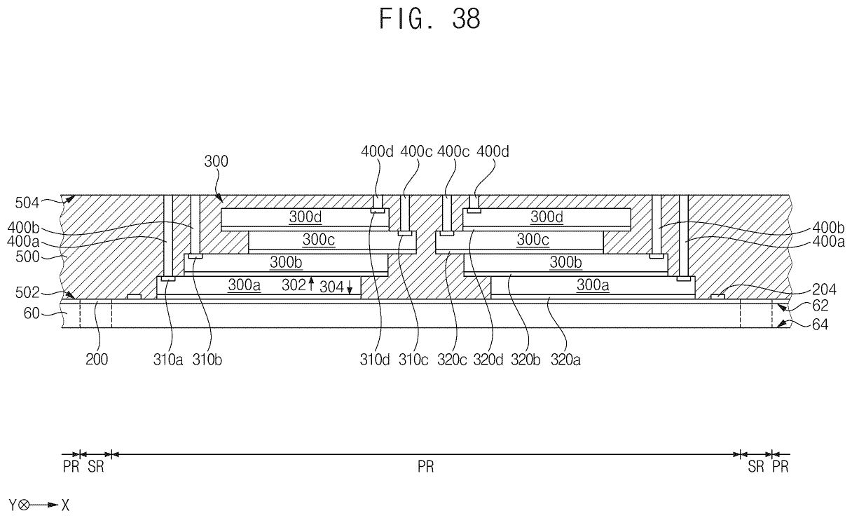

Referring to FIGS. 37 and 38, a molding member 500 may be formed on the upper redistribution wiring layer 200 on the carrier substrate 60 to cover the plurality of semiconductor chips 300.

In example embodiments, a molding material may be formed on an upper surface of the upper redistribution wiring layer 200 to cover the plurality of semiconductor chips 300 and the conductive pillars 400a, 400b, 400c, 400d, and an upper portion of the molding material may be partially removed using a grinding apparatus GA to have a desired height, to form the molding member 500. At this time, end portions of the conductive pillars 400a, 400b, 400c, 400d may be partially removed together.

The molding member 500 may be formed to completely cover the plurality of semiconductor chips 300. The molding member 500 may have a first surface 504 and a second surface 502 opposite to the first surface 504. The second surface 502 of the molding member 500 may contact the upper redistribution wiring layer 200. End portions of the conductive pillars 400a, 400b, 400c, 400d may be exposed from the first surface 504 of the molding member 500.

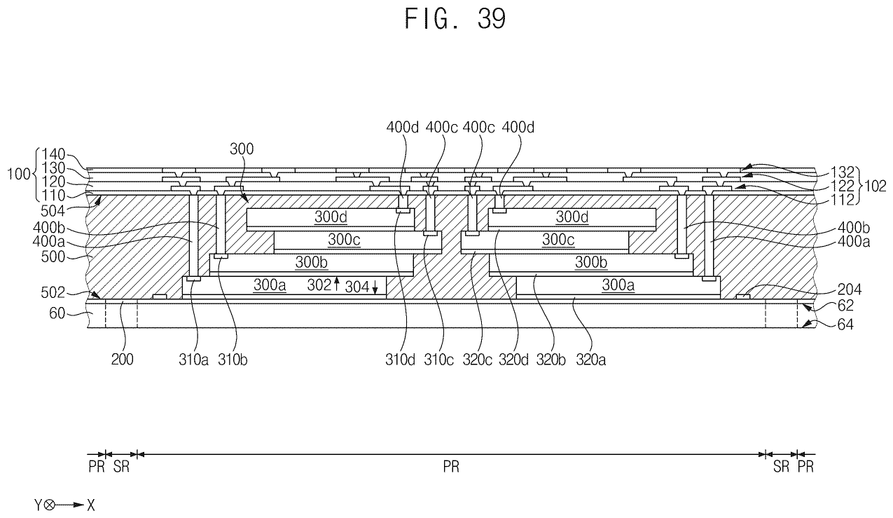

Referring to FIG. 39, processes the same as or similar to the processes described with reference to FIG. 31 may be performed to form a lower redistribution wiring layer 100 on the first surface 504 of the molding member 500. The lower redistribution wiring layer 100 may have redistribution wirings 102 electrically connected to the conductive pillars 400a, 400b, 400c, 400d.

The lower redistribution wiring layer 100 as a front redistribution layer (FRDL) may include first to fourth lower insulating layers 110, 120, 130, 140 stacked on one another and the redistribution wirings 102 within the first to fourth lower insulating layers 110, 120, 130, 140. The redistribution wirings 102 may include first, second and third lower redistribution wirings 112, 122, 132.

It will be understood that the number, size, arrangement, etc. of the lower insulating layers and the redistribution wirings of the lower redistribution wiring layer are provided as an example, and the present inventive concept is not limited thereto.

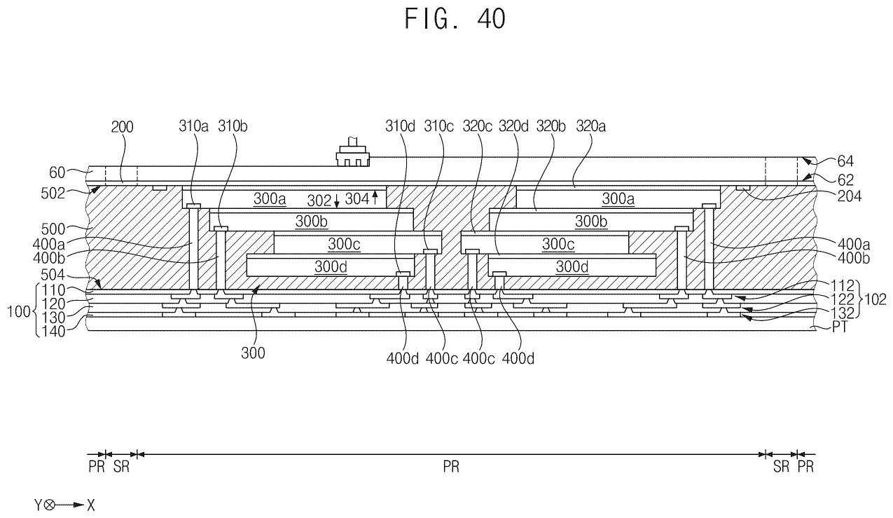

Referring to FIGS. 40 to 42, a carrier substrate 60 may be ground to form a marking layer 600 of a desired thickness, and a marking pattern 610 may be formed in an outer surface of the marking layer 600.

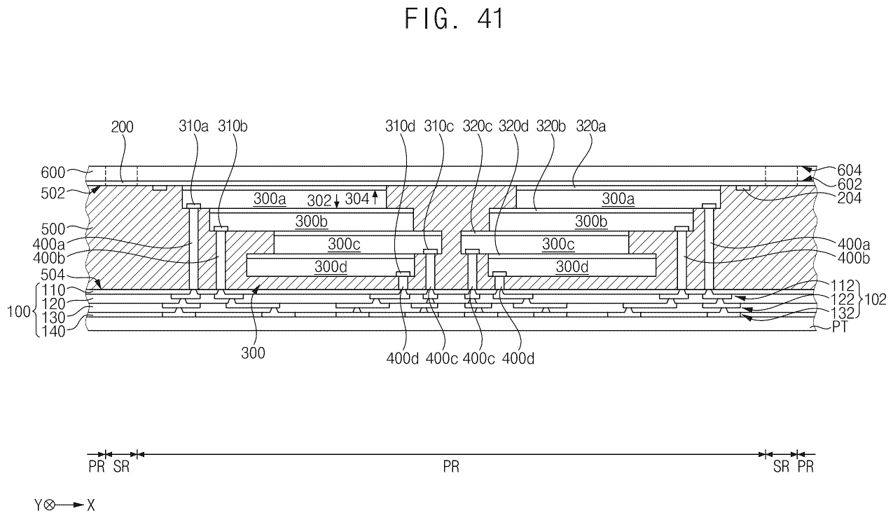

As illustrated in FIGS. 40 and 41, a protective tape PT may be attached on the lower redistribution wiring layer 100, the structure of FIG. 39 may be turned over, and a backside surface 64 of the carrier substrate 60 may be ground to form the marking layer 600 of a desired thickness.

For example, the backside surface 64 of the carrier substrate 60 may be partially removed by a grinding apparatus GA. The thickness of the marking layer 600 may be within a range of 20 μm to 100 μm. The marking layer 600 may be a silicon layer including silicon. The marking layer 600 including silicon may have a thermal conductivity of about 139.4 W/mK. The thermal conductivity of the molding member 500 may be within a range of 1.8 W/mK to 3 W/mK.

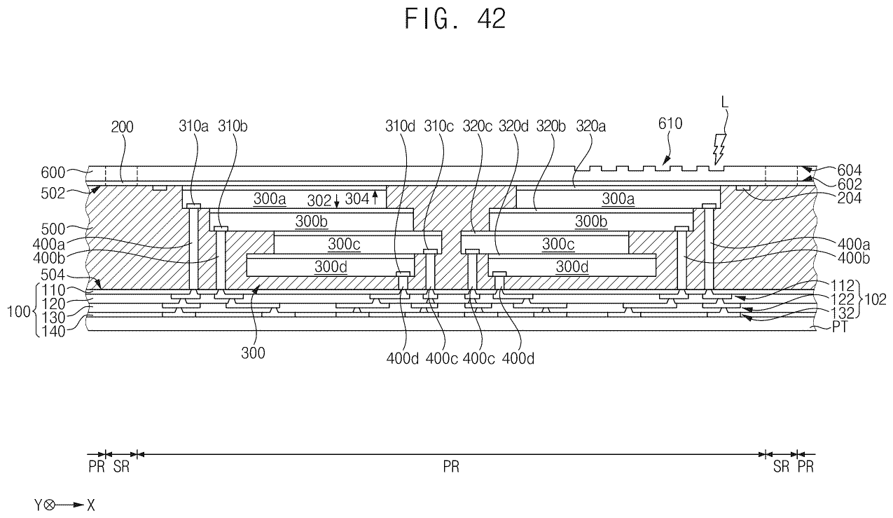

As illustrated in FIG. 42, the marking pattern 610 may be formed by irradiating a laser L on the outer surface 604 of the marking layer 600. The marking pattern 610 may be formed by a laser processing device. The laser processing device may include a scanner optical system to form an engraved pattern in the outer surface 604 of the marking layer 600. The engraved pattern may indicate a manufacturer, a manufacturing date, a serial number, etc. The laser may form openings in the backside surface 610 of the marking layer 610, and the engraved pattern may be defined by the openings. The opening may include a groove having a preset depth.

Then, the protective tape PT is removed, external connection members 160 (see FIG. 35) may be formed on lower bonding pads of the lower redistribution wiring layer 100, and the lower redistribution wiring layer 100, the upper redistribution wiring layer 200, the molding member 500, and the marking layer 600 may be cut along the cutting region SR to complete the semiconductor package 11 of FIG. 35.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

According to example embodiments, in a method of manufacturing a semiconductor package, an upper redistribution wiring layer is formed on a carrier substrate. A plurality of semiconductor chips are sequentially stacked on the upper redistribution wiring layer such that a backside surface opposite to a front surface on which chip pads are formed faces the upper redistribution wiring layer. Conductive pillars are formed to extending substantially vertically on the chip pads of the plurality of semiconductor chips. A molding member is formed on the upper redistribution wiring layer to cover the plurality of semiconductor chips and the conductive pillars. A lower redistribution wiring layer is formed on the molding member, the lower redistribution wiring layer having redistribution wirings electrically connected to the conductive pillars, respectively. A backside surface of the carrier substrate is ground to form a marking layer having a desired thickness. A marking pattern is formed in an outer surface of the marking layer.

In example embodiments, forming the upper redistribution wiring layer may include forming an insulating layer on the carrier substrate; and forming an align key pattern on the insulating layer.

In example embodiments, sequentially stacking the plurality of semiconductor chips may include stacking first and second semiconductor chips on the upper redistribution wiring layer in a cascade manner, the first semiconductor chip may include an overhang portion protruding from one side of the second semiconductor chip, and chip pads of the first semiconductor chip may be provided on a lower surface of the overhang portion.

In example embodiments, forming the conductive pillars on the chip pads of the plurality of semiconductor chips may include forming a seed layer on a front surface of the first semiconductor chip on the upper redistribution wiring layer, forming a first photoresist pattern having first openings that expose chip pad regions on the seed layer, performing a plating process to fill the first openings of the first photoresist pattern with a conductive material to form the conductive pillars, removing the first photoresist pattern, and removing a portion of the seed layer exposed by the conductive pillars to form a seed layer pattern.

In example embodiments, the method may further include forming an intermediate redistribution wiring layer on the molding member, sequentially stacking a plurality of lower semiconductor chips on the intermediate redistribution wiring layer such that a backside surface opposite to a front surface on which chip pads are formed faces the intermediate redistribution wiring layer, forming lower conductive pillars extending substantially vertically on the chip pads of the plurality of lower semiconductor chips, and forming a lower molding member on the intermediate redistribution wiring layer to cover the plurality of lower semiconductor chips and the lower conductive pillars. The lower redistribution wiring layer may be formed on the lower molding member, and the conductive pillars may be electrically connected to the redistribution wirings, respectively.

In example embodiments, forming the intermediate redistribution wiring layer may include forming a second insulating layer on the molding member, and forming a second align key pattern on the second insulating layer.

In example embodiments, the method may further include forming connection pads on the intermediate redistribution wiring layer to be electrically connected to the conductive pillars, and forming conductive connection pillars extending substantially vertically on the connection pads. The conductive connection pillars may be electrically connected to the redistribution wirings, respectively.

In example embodiments, grinding the backside surface of the carrier substrate may include partially removing the backside surface of the carrier substrate using a grinding apparatus.

In example embodiments, the carrier substrate may include silicon.

In example embodiments, the marking layer may have a thickness within a range of 20 μm to 100 μm.

According to example embodiments, in a method of manufacturing a semiconductor package, an upper encapsulation structure is formed on a carrier substrate. A lower encapsulation structure is formed on the upper encapsulation structure. A lower redistribution wiring layer is formed on the lower encapsulation structure, the lower redistribution wiring layer having redistribution wirings. A backside surface of the carrier substrate is ground to form a marking layer having a desired thickness. A marking pattern is formed in an outer surface of the marking layer. Forming the upper encapsulation structure includes forming an upper redistribution wiring layer on the carrier substrate; sequentially stacking a plurality of upper semiconductor chips on the upper redistribution wiring layer such that a backside surface opposite to a front surface on which chip pads are formed faces the upper redistribution wiring layer; forming upper conductive pillars extending substantially vertically on the chip pads of the plurality of upper semiconductor chips; and forming an upper molding member on the upper redistribution wiring layer to cover the plurality of upper semiconductor chips and the upper conductive pillars. Forming the lower encapsulation structure includes forming an intermediate redistribution wiring layer on the upper molding member; sequentially stacking a plurality of lower semiconductor chips on the intermediate redistribution wiring layer such that a backside surface opposite to a front surface on which chip pads are formed faces the intermediate redistribution wiring layer; forming lower conductive pillars extending substantially vertically on the chip pads of the plurality of intermediate semiconductor chips; and forming a molding member on the intermediate redistribution wiring layer to cover the plurality of lower semiconductor chips and the lower conductive pillars.

In example embodiments, forming the upper redistribution wiring layer may include forming a first insulating layer on the carrier substrate, and forming a first align key pattern on the first insulating layer.

In example embodiments, sequentially stacking the plurality of lower semiconductor chips may include stacking first and second semiconductor chips on the upper redistribution wiring layer in a cascade manner, the first semiconductor chip may include an overhang portion protruding from one side of the second semiconductor chip, and chip pads of the first semiconductor chip may be provided on a lower surface of the overhang portion.

In example embodiments, forming the lower conductive pillars on the chip pads of the plurality of lower semiconductor chips may include forming a seed layer on a front surface of the first semiconductor chip on the upper redistribution wiring layer, forming a first photoresist pattern having first openings that expose chip pad regions on the seed layer, performing a plating process to fill the first openings of the first photoresist pattern with a conductive material to form the lower conductive pillars, removing the first photoresist pattern, and removing a portion of the seed layer exposed by the lower conductive pillars to form a seed layer pattern.

In example embodiments, forming the intermediate redistribution wiring layer may include forming a second insulating layer on the upper molding member, and forming a second align key pattern on the second insulating layer.

In example embodiments, the method may further include forming connection pads on the intermediate redistribution wiring layer to be electrically connected to the upper conductive pillars and forming conductive connection pillars extending substantially vertically on the connection pads, and the conductive connection pillars may be electrically connected to the redistribution wirings, respectively.

In example embodiments, grinding the backside surface of the carrier substrate may include partially removing the backside surface of the carrier substrate using a grinding apparatus.

In example embodiments, the carrier substrate may include silicon.

In example embodiments, the marking layer has a thickness within a range of 20 μm to 100 μm.

According to example embodiments, in a method of manufacturing a semiconductor package, an upper redistribution wiring layer is formed on a carrier substrate. A plurality of upper semiconductor chips is sequentially stacked on the upper redistribution wiring layer such that a backside surface opposite to a front surface on which chip pads are formed faces the upper redistribution wiring layer. Upper conductive pillars are formed to extend substantially vertically on the chip pads of the plurality of upper semiconductor chips. A lower molding member is formed on the upper redistribution wiring layer to cover the plurality of upper semiconductor chips and the upper conductive pillars. An intermediate redistribution wiring layer is formed on the lower molding member, the intermediate redistribution wiring layer having connection pads electrically connected to the upper conductive pillars. A plurality of lower semiconductor chips is sequentially stacked on the intermediate redistribution wiring layer such that a backside surface opposite to a front surface where chip pads are formed faces the intermediate redistribution wiring layer. Lower conductive pillars are formed to extend substantially vertically on the chip pads of the plurality of lower semiconductor chips. Conductive connection pillars are formed to extend substantially vertically on the connection pads. A lower molding member is formed on the intermediate redistribution wiring layer to cover the plurality of lower semiconductor chips, the lower conductive pillars, and the conductive connection pillars. A lower redistribution wiring layer is formed on the lower molding member, the lower redistribution wiring layer having redistribution wirings electrically connected to the lower conductive pillars and the conductive connection pillars respectively. A backside surface of the carrier substrate is ground to form a marking layer having a desired thickness. A marking pattern is formed in an outer surface of the marking layer.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a lower redistribution wiring layer having redistribution wirings;
a molding member stacked on the lower redistribution wiring layer, the molding member having a first surface facing the lower redistribution wiring layer and a second surface opposite to the first surface;
a plurality of semiconductor chips sequentially stacked within the molding member and arranged such that front surfaces on which chip pads are formed face the lower redistribution wiring layer;
conductive pillars extending substantially vertically from the chip pads within the molding member and electrically connected to the redistribution wirings, respectively;
an upper redistribution wiring layer provided on the second surface of the molding member; and
a silicon layer provided on the upper redistribution wiring layer and having a marking pattern formed in an outer surface of the silicon layer.

2. The semiconductor package of claim 1, wherein the silicon layer having a thickness within a range of 20 μm to 100 μm.

3. The semiconductor package of claim 1, wherein the marking pattern includes a groove having a preset depth from the outer surface of the silicon layer.

4. The semiconductor package of claim 1, wherein the conductive pillars include copper (Cu).

5. The semiconductor package of claim 1, wherein the upper redistribution wiring layer has an align key pattern formed on a lower surface of the upper redistribution wiring layer that contacts the second surface of the molding member.

6. The semiconductor package of claim 1, wherein the plurality of semiconductor chips include first and second semiconductor chips that are stacked in a cascade manner from a lower surface of the upper redistribution wiring layer,
wherein the first semiconductor chip includes an overhang portion protruding from one side of the second semiconductor chip, and
wherein chip pads of the first semiconductor chip are provided on a lower surface of the overhang portion.

7. The semiconductor package of claim 1, further comprising:
a lower molding member interposed between the lower redistribution wiring layer and the molding member, the lower molding member having a third surface in contact with the lower redistribution wiring layer and a fourth surface opposite to the third surface;
a plurality of lower semiconductor chips sequentially stacked within the lower molding member and arranged such that front surfaces on which chip pads are formed face the lower redistribution wiring layer;
lower conductive pillars extending substantially vertically from the chip pads within the lower molding member and electrically connected to the redistribution wirings respectively; and
an intermediate redistribution wiring layer provided on the fourth surface of the lower molding member.

8. The semiconductor package of claim 7, wherein the intermediate redistribution wiring layer has a second align key pattern formed on a lower surface of the intermediate redistribution wiring layer that contacts the fourth surface of the lower molding member.

9. The semiconductor package of claim 7, wherein the plurality of lower semiconductor chips include third and fourth semiconductor chips that are stacked in a cascade manner from a lower surface of the intermediate redistribution wiring layer,
wherein the third semiconductor chip includes an overhang portion protruding from one side of the fourth semiconductor chip, and
wherein chip pads of the third semiconductor chip are provided on a lower surface of the overhang portion.

10. The semiconductor package of claim 7, further comprising:
connection pads provided on the lower surface of the intermediate redistribution wiring layer and electrically connected to the conductive pillars exposed from the first surface of the molding member, respectively; and
conductive connection pillars extending substantially vertically from the connection pads within the lower molding member and electrically connected to the redistribution wirings, respectively.

11. A semiconductor package, comprising:
a lower redistribution wiring layer having redistribution wirings;
a first encapsulation structure stacked on the lower redistribution wiring layer;
a second encapsulation structure stacked on the first encapsulation structure; and
a silicon layer provided on the second encapsulation structure and having a marking pattern formed in an outer surface of the silicon layer,
wherein the first encapsulation structure includes:
a lower molding member having a first surface in contact with the lower redistribution wiring layer and a second surface opposite to the first surface;
a plurality of lower semiconductor chips sequentially arranged within the lower molding member such that front surfaces on which chip pads are formed face the lower redistribution wiring layer;
lower conductive pillars extending substantially vertically from the chip pads within the lower molding member and electrically connected to the redistribution wirings, respectively; and
an intermediate redistribution wiring layer provided on the second surface of the lower molding member, and
wherein the second encapsulation structure includes:
an upper molding member having a third surface in contact with the intermediate redistribution wiring layer and a fourth surface opposite to the third surface;
a plurality of upper semiconductor chips sequentially arranged within the upper molding member such that front surfaces on which chip pads are formed face the lower redistribution wiring layer;
upper conductive pillars extending substantially vertically from the chip pads within the upper molding member; and
an upper redistribution wiring layer provided on the fourth surface of the upper molding member.

12. The semiconductor package of claim 11, wherein the silicon layer has a thickness within a range of 20 μm to 100 μm.

13. The semiconductor package of claim 11, wherein the marking pattern includes a groove having a preset depth from the outer surface of the silicon layer.

14. The semiconductor package of claim 11, wherein the lower conductive pillars and the upper conductive pillars include copper (Cu).

15. The semiconductor package of claim 11, wherein the upper redistribution wiring layer has an upper align key pattern formed on a lower surface of the upper redistribution wiring layer that contacts the fourth surface of the upper molding member.

16. The semiconductor package of claim 11, wherein the intermediate redistribution wiring layer has a lower align key pattern formed on a lower surface of the intermediate redistribution wiring layer that contacts the second surface of the lower molding member.

17. The semiconductor package of claim 16, further comprising:
connection pads are provided on the lower surface of the intermediate redistribution wiring layer and electrically connected to the upper conductive pillars exposed from the third surface of the upper molding member, respectively; and
conductive connection pillars extending substantially vertically from the connection pads within the lower molding member and electrically connected to the redistribution wirings, respectively.

18. The semiconductor package of claim 11, wherein the plurality of upper semiconductor chips include first and second semiconductor chips that are stacked in a cascade manner from a lower surface of the upper redistribution wiring layer,
wherein the first semiconductor chip includes an overhang portion protruding from one side of the second semiconductor chip, and
wherein chip pads of the first semiconductor chip are provided on a lower surface of the overhang portion.

19. The semiconductor package of claim 11, wherein the plurality of lower semiconductor chips include third and fourth semiconductor chips that are stacked in a cascade manner from a lower surface of the intermediate redistribution wiring layer,
wherein the third semiconductor chip includes an overhang portion protruding from one side of the fourth semiconductor chip, and
wherein chip pads of the third semiconductor chip are provided on a lower surface of the overhang portion.

20. A semiconductor package, comprising:
a lower redistribution wiring layer having redistribution wirings;
a lower molding member stacked on the lower redistribution wiring layer and having a first surface facing the lower redistribution wiring layer and a second surface opposite to the first surface;
a plurality of lower semiconductor chips sequentially arranged within the lower molding member such that front surfaces on which chip pads are formed face the lower redistribution wiring layer;
lower conductive pillars extending substantially vertically from the chip pads within the lower molding member and electrically connected to the redistribution wirings, respectively;
an intermediate redistribution wiring layer provided on the second surface of the lower molding member;
an upper molding member having a third surface contacting the intermediate redistribution wiring layer and a fourth surface opposite to the third surface;
a plurality of upper semiconductor chips sequentially arranged within the upper molding member such that front surfaces on which chip pads are formed faces the intermediate redistribution wiring layer;
upper conductive pillars extending substantially vertically from the chip pads within the upper molding member;
an upper redistribution wiring layer provided on the fourth surface of the upper molding member; and
a silicon layer provided on the upper redistribution wiring layer and having a marking pattern formed in an outer surface of the silicon layer.
